(19) United States
(12) Patent Application Publication
(10) Pub. No.: US 2026/0198238 A1
(43) Pub. Date: Jul. 9, 2026

(54) Processing of Semiconductor Workpieces

(71) Applicant: Wolfspeed, Inc., Durham, NC (US)

(72) Inventors: Simon Bubel, Carrboro, NC (US); Yuri I. Khlebnikov, Raleigh, NC (US); Alexander Kevin Shveyd, Chapel Hill, NC (US); Jong Hyup Lee, Cary, NC (US)

(21) Appl. No.: 19/012,381

(22) Filed: Jan. 7, 2025

(51) Int. Cl. H01L 21/02; H01L 21/683

(52) U.S. Cl. CPC H10P 14/6681; H10P 14/683; H10P 14/6922; H10P 72/74; H10P 72/7412

(57) ABSTRACT

A semiconductor wafer is provided. The wafer comprises a first layer including a semiconductor material and a second layer including a cured furan- or ether-based resin bonded to the first layer. A semiconductor device package is also provided. The semiconductor device package comprises a semiconductor die and one more terminals protruding from the semiconductor device package. The semiconductor die comprises a first layer comprising a semiconductor material and a second layer comprising a cured resin bonded to the first layer.

### FIELD

The present disclosure relates generally to semiconductor workpieces and semiconductor device fabrication, and more particularly to processing of semiconductor workpieces, such as silicon carbide semiconductor boules or wafers.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices.

Power semiconductor devices may be packaged into various semiconductor device packages, such as discrete semiconductor device packages and power modules. Power modules may include one or more power devices and other circuit components and can be used, for instance, to dynamically switch large amounts of power through various components, such as motors, inverters, generators, and the like.

Semiconductor devices may be fabricated from wide bandgap semiconductor materials, such as silicon carbide and/or Group III-nitride based semiconductor materials. The fabrication process for power semiconductor devices may require processing of wide bandgap semiconductor wafers, such as silicon carbide semiconductor wafers.

### SUMMARY

Aspects and advantages of embodiments of the present disclosure will be set forth in part in the following description, or can be learned from the description, or can be learned through practice of the embodiments.

In one aspect, the present disclosure provides an example semiconductor wafer. In some implementations, the example wafer includes a first layer comprising a semiconductor material. In some implementations, the example wafer includes a second layer comprising a cured furan- or ether-based resin bonded to the first layer.

In another aspect, the present disclosure provides an example semiconductor wafer. In some implementations, the example wafer includes a first layer comprising a semiconductor material and having a thickness of about 50 μm or less. In some implementations, the example wafer includes a second layer comprising a cured ether- or furan-based resin bonded to the first layer.

In another aspect, the present disclosure provides an example semiconductor device package. In some implementations, the example semiconductor device package includes a semiconductor die and one more terminals protruding from the semiconductor device package, wherein the semiconductor die includes a first layer comprising a semiconductor material and a second layer comprising a cured resin bonded to the first layer.

In another aspect, the present disclosure provides an example process. In some implementations, the example process includes applying a liquid precursor material to a surface of a semiconductor material. In some implementations, the example process includes curing the liquid precursor material to form a semiconductor wafer comprising a first layer of the semiconductor material and a second layer of cured resin. In some implementations, the example process includes forming a semiconductor device package comprising a semiconductor die formed from the semiconductor wafer.

In another aspect, the present disclosure provides an example process. In some implementations, the example process includes at least partially curing the liquid precursor material to form a semiconductor wafer comprising a first layer of the semiconductor material and a second layer of cured resin. In some implementations, the example process includes separating the semiconductor wafer from the boule.

In another aspect, the present disclosure provides an example process. In some implementations, the example process includes applying a liquid precursor material to a surface of the semiconductor material. In some implementations, the example process includes at least partially curing the liquid precursor material to form a semiconductor wafer comprising the semiconductor material and a layer of cured resin. In some implementations, the example process includes separating a layer of semiconductor material from a remaining portion of the semiconductor material.

In another aspect, the present disclosure provides an example process. In some implementations, the example process includes applying a liquid precursor material to a surface of the semiconductor wafer. In some implementations, the example process includes at least partially curing the liquid precursor material to form a semiconductor wafer comprising the semiconductor material and a layer of cured resin. In some implementations, the example process includes separating a semiconductor die from the semiconductor wafer.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 is a first perspective view crystal plane diagram showing the coordinate system for a hexagonal crystal such as 4H—SiC.

FIG. 2 is a second perspective view crystal plane diagram for a hexagonal crystal, illustrating a vicinal plane that is non-parallel to the c-plane.

FIG. 3A is a perspective view wafer orientation diagram showing orientation of a vicinal wafer relative to the c-plane.

FIG. 3B is a simplified cross-sectional view of the vicinal wafer of FIG. 3A superimposed over a portion of a boule.

FIG. 3C is a perspective view of a wafer orientation diagram showing orientation of an on-axis wafer relative to the c-plane.

FIG. 3D is simplified cross-sectional view of the wafer of FIG. 3C superimposed over a portion of a boule.

FIG. 4 is a top plan view of an exemplary silicon carbide semiconductor wafer, with superimposed arrows showing crystallographic orientation directions.

FIG. 5A is a side elevation schematic view of an on-axis boule of crystalline material.

FIG. 5B is a side elevation schematic view of the boule of FIG. 5A being rotated by 4 degrees, with a superimposed pattern for cutting end portions of the boule.

FIG. 5C is a side elevation schematic view of a boule following removal of end portions to provide end faces that are non-perpendicular to the c-direction.

FIG. 5D is a side elevation schematic view of an off-axis grown boule of crystalline material.

FIG. 5E is a side elevation schematic view of an off-axis grown boule having end faces that are non-perpendicular to the c-direction.

FIG. 6 depicts an example embodiment of a two layer semiconductor wafer according to the present disclosure.

FIG. 7 depicts an example embodiment of a three layer semiconductor wafer according to the present disclosure.

FIGS. 8A, 8B, and 8C depict example embodiments of a semiconductor wafer having a non-uniform support layer according to the present disclosure.

FIG. 9A depicts an example embodiment of a semiconductor wafer having a non-uniform support layer according to the present disclosure.

FIG. 9B depicts a cross-section of an example embodiment of a semiconductor wafer having a via passing through a support layer according to the present disclosure.

FIG. 10 depicts an overview of an example method and system according to examples of the present disclosure.

FIG. 11 depicts an overview of an example method and system according to examples of the present disclosure.

FIG. 12 depicts an overview of an example method and system according to examples of the present disclosure.

FIG. 13 depicts an example embodiment of a semiconductor wafer according to the present disclosure.

FIG. 14 depicts a flowchart according to an example method of the present disclosure.

FIG. 15 depicts a flowchart according to an example method of the present disclosure.

Repeat use of reference characters in the present specification and drawings is intended to represent the same and/or analogous features or elements of the present invention.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Power semiconductor devices are often fabricated from wide bandgap semiconductor materials, such as silicon carbide or group III-nitride based semiconductor materials (e.g., gallium nitride). Herein, a wide bandgap semiconductor material refers to a semiconductor material having a bandgap greater than 1.40 eV. Aspects of the present disclosure are discussed with reference to silicon carbide-based semiconductor structures as wide bandgap semiconductor structures. Those of ordinary skill in the art, using the disclosures provided herein, will understand that the technology according to example embodiments of the present disclosure may be used with any semiconductor material, such as other wide bandgap semiconductor materials, without deviating from the scope of the present disclosure. Example wide bandgap semiconductor materials include silicon carbide and the group III-nitrides.

Power semiconductor devices may be fabricated using epitaxial layers formed on a semiconductor workpiece, such as a silicon carbide semiconductor wafer. Aspects of the present disclosure are discussed with reference to a semiconductor workpiece that is a semiconductor wafer that includes silicon carbide (“silicon carbide semiconductor wafer”) for purposes of illustration and discussion. Those of ordinary skill in the art, using the disclosures provided herein, will understand that aspects of the present disclosure can be used with other semiconductor workpieces, such as other wide bandgap semiconductor workpieces. Other semiconductor workpieces may include carrier substrates, ingots, boules, polycrystalline substrates, monocrystalline substrates, bulk materials having a thickness of greater than 1 millimeter, such as greater than about 5 millimeters, such as greater than about 10 millimeters, such as greater than about 20 millimeters, such as greater than about 50 millimeters, such as greater than about 100 millimeters, such as greater than about 200 millimeters, etc.

In some examples, the semiconductor workpiece includes silicon carbide crystalline material. The silicon carbide crystalline material may have a 4H crystal structure, 6H crystal structure, or other crystal structure. The semiconductor workpiece can be an on-axis workpiece (e.g., end face parallel to the (0001) plane) or an off-axis workpiece (e.g., end face non-parallel to the (0001) plane).

Aspects of the present disclosure may make reference to a surface of the semiconductor workpiece. In some examples, the surface of the workpiece may be, for instance, a silicon face of the workpiece. In some examples, the surface of the workpiece may be, for instance, a carbon face of the workpiece.

In some examples, a semiconductor wafer may be a solid semiconductor workpiece upon which semiconductor device fabrication may be implemented. A semiconductor wafer may be a homogenous material, such as silicon carbide, and may provide mechanical support for the formation and/or carrying of additional semiconductor layers (e.g., epitaxial layers), metallization layers, and other layers to form one or more semiconductor devices. In some examples, a semiconductor wafer may have a thickness in a range of about 0.2 microns to about 1000 microns, or greater.

A semiconductor wafer may be characterized by a plurality of surfaces. For example, a semiconductor wafer may have a “first major surface” and a “second major surface.” The first major surface may be generally opposite the second major surface. The first and second major surfaces may be generally parallel to one another. A semiconductor wafer may also have a “side surface” corresponding to a surface extending between the two major surfaces. For example, the side surface may extend between the first major surface and the second major surface.

Power semiconductor device fabrication processes may include surface processing operations that are performed on the silicon carbide semiconductor wafer to prepare one or more surfaces of the silicon carbide semiconductor wafer for later processing operations, such as surface

implantation, formation of epitaxial layers, metallization, etc. Example surface processing operations may include grinding operations, lapping operations, and polishing operations. Methods for surface processing of semiconductor wafers in semiconductor manufacturing may include grinding, lapping, and/or polishing the rough surfaces until a sufficient smoothness and/or thickness is achieved.

Grinding is a material removal process that is used to remove material from the semiconductor wafer. Grinding may be used to reduce a thickness of a semiconductor wafer. Grinding typically involves exposing the semiconductor wafer to an abrasive comprising surface, such as grinding teeth on a grind wheel. Grinding may remove material of the semiconductor wafer through engagement with the abrasive surface.

Lapping is a precision finishing process that uses a loose abrasive in slurry form. The slurry typically includes coarser particles (e.g., largest dimension of the particles being greater than about 100 microns) to remove material from the semiconductor wafer. Lapping typically does not include engaging the semiconductor wafer with an abrasive-containing surface on the lapping tool (e.g., a wheel or disc having an abrasive-containing surface). Instead, the semiconductor wafer typically comes into contact with a lapping plate or a tile usually made of metal. Lapping typically provides better planarization of the semiconductor wafer relative to grinding.

Polishing is a process to remove imperfections and create a very smooth surface with a low surface roughness. Polishing may be performed using a slurry and a polishing pad. The slurry typically includes finer particles relative to lapping, but coarser particles relative to chemical mechanical planarization (CMP). Polishing typically provides better planarization of the semiconductor wafer relative to grinding.

CMP is a type of fine or ultrafine polishing, typically used to produce a smoother surface ready, for instance, for epitaxial growth of layers on the semiconductor wafer. CMP may be performed chemically and/or mechanically to remove imperfections and to create a very smooth and flat surface with low surface roughness. CMP typically involves changing the material of the semiconductor through a chemical process (e.g., oxidation) and removing the new material from the semiconductor wafer through abrasive contact with a slurry and/or other abrasive surface or polishing pad (e.g., oxide removal). In CMP, the abrasive elements in the slurry typically remove the product of the chemical process and do not remove the bulk material of the semiconductor wafer, often leaving very low subsurface damage.

Methods for fabricating power semiconductor devices include forming a crystalline material boule, such as a silicon carbide boule, and separating portions of the boule to form substrates, such as silicon carbide semiconductor wafers. In some instances, boules may be formed to include doped regions with dopants within the crystalline material boule.

Methods for forming semiconductor wafers from boules may include, for instance, cutting thin layers (e.g., wafers) from the boule using wire saws. Another example removal process for forming semiconductor wafers from boules may include a laser-based removal process (e.g., laser splitting). Laser-based removal processes may include providing subsurface laser damage patterns to a boule to form weakened areas in the boule. Portions may then be separated from the boule along the weakened areas to produce semiconductor wafers. Separation processes may include, for example, ultrasonic fracturing, mechanical force fracturing, or other fracturing methods.

Typically, the wafer substrate thickness is defined based on physical requirements such as shape stability, thermal conduction, electric conduction, robot handling requirements, etc. Subsequently, the wafer thickness is created by separating the wafer from an ingot or crystal boult at a designed thickness to yield a final wafer thickness after surface machining operations, such as grinding and polishing operations.

Typically, only the semiconductor material thickness determines the wafer thickness. This leads to consumption of costly ingot or semiconductor boule material to satisfy physical wafer requirements that do not require a specific crystallographic characteristic for which the semiconductor material was chosen. Mechanical properties and thermal and electrical conduction of the wafer can also be achieved with different materials that can be bonded to the semiconductor surface. As such, wafers are described herein that comprise a layer of material in addition to the semiconductor material. The additional layer can help to satisfy the mechanical, thermal and/or electrical conduction properties while allowing the semiconductor material to be thinner in order to reduce or eliminate the use of unnecessary semiconductor material. For example, this allows the semiconductor wafer thickness to be chosen independently from the above physical requirements and can make the semiconductor thickness solely a function of epitaxy requirements, which are usually satisfied with a thickness of a couple of micrometers.

While it is known to use temporary carrier substrates in semiconductor manufacturing for mechanical purposes, the additional layer or layers described herein are not temporary and become a part of the wafer and remain a part of the wafer through subsequent processing operations, die singulation, and device packaging. Further, the additional layer can be applied even prior to wafer separation from the ingot or crystal boule by applying a liquid precursor to a surface of the boule, at least partially curing the precursor, and separating a thin slice of semiconductor material backed by the hardened precursor.

As mentioned, in one embodiment, the additional layer can be applied during the wafer separation process (e.g., a laser separation process). A semiconductor boule surface can be prepared through surface machining methods to make it suitable for a laser fracturing process. Then, a laser fracturing process can be conducted, resulting in a fracture formation under at least part of the prepared surface at a defined depth. As explained above, the defined depth can be based on the final semiconductor material thickness being the minimal semiconductor thickness required for the wafer product.

After laser fracturing, a precursor material can be applied to the surface of the boule above the fracture. The precursor material can then be at least partially cured by any suitable method (e.g., an external stimulus). The wafer can then be separated from the boule resulting in a semiconductor wafer comprising a layer of semiconductor material and a layer of at least partially cured (e.g., crosslinked, calcinated, sintered, crystallized, etc.) precursor material attached to create a minimum thickness of the multilayer wafer.

In another embodiment, the thin semiconductor layer is first separated from the boule, and the liquid precursor material is added to the backside of the thin semiconductor to create a multilayer wafer.

In further processing operations, the semiconductor wafer surface and the backside of the wafer (e.g., comprising the crosslinked layer) can be subjected to surface processing methods and/or the wafer can be subjected to an annealing operation, further hardening the precursor material or activating its physical properties. The annealing operation may be part of an epitaxy operation or post implantation or metallization operation.

As the physical properties of the hardened precursor material can be chosen to create a wafer with required mechanical properties and physical properties, such as backside electrical conductivity and thermal conductivity, all or part of the hardened backside material can remain on the semiconductor and become part of the finished device.

In one embodiment, the precursor material is a furan- or ether-based curable liquid that may comprise a solvent and functional components to adjust the properties of the material before and/or after hardening. In some embodiments, for example, the functional components can include glycolate functionalized metals, metalloids, or their silicides, carbides, nitrides, or oxides. In some embodiments, the functional groups comprise glycolate, diethylene glycolate, or glycerolate. In some embodiments, the functional compounds can include silicon carbide, tantalum, niobium, tungsten, hafnium, titanium, and/or molybdenum or their silicides, carbides, nitrides, or oxides.

In some embodiments, the liquid precursor material comprises a solvent. The solvent may be selected or modified to form a layer on the semiconductor surface with desired properties. For example, the solvent can be selected or modified to have suitable wettability, rheology, evaporation rate, or curing properties. In some embodiments, the solvent is selected or modified based on desired shelf life, storage conditions, or environmental safety or health considerations.

In some embodiments, the liquid precursor comprises a plasticizer. The plasticizer may be selected or modified to change wettability, rheology, or curing properties. The curing properties can be changed to affect mechanical properties of the partially cured layer as well as mechanical properties of the fully cured layer.

The liquid precursor material can be applied to the boule, ingot, or semiconductor wafer material by any suitable liquid processing method. For example, the liquid application process can involve the control of the ambient atmosphere, pressure, and/or temperature. In some embodiments, temperature control is achieved via a radiation source or via a temperature-controlled wafer fixture or chuck. In some embodiments, the liquid processing method involves multiple operations, such as conditioning the semiconductor surface or post processing of the precursor material in addition to the application operation.

Suitable liquid processing methods can involve spin-coating, slip casting, doctor blading, dipping, screen printing, stamping, spray coating, brushing or rolling, condensation, electrostatic deposition, lamination, etc. In some embodiments the liquid precursor material can be partially cured prior to its application to the semiconductor surface. In some embodiments, a patterning of the precursor material can be employed to influence wafer shape behavior. For example, patterning can be employed to change stiffness, friability, or plasticity in certain regions, at ambient conditions or conditions (e.g., temperature) of layer processing operations such as epitaxy or ion implantation. Patterning of the additional layer can also be employed to influence mechanical properties for further processing such as processing wafer dimensions, die dimensions, lithography stepper ranges, etc. The patterning can be a function of the precursor application, of post-application treatment of the precursor layer, of the crosslinked layer, or of the hardened layer. Patterning of the precursor, partially cured, or fully cured layer can be part of a multi-layer system involving one or more patterned layers and may include unpatterned layers.

In some embodiments, a semiconductor wafer with a first, second, or more layers of liquid processed material can be optimized to provide mechanical and physical properties through a series of semiconductor process steps. At a later step, part of the liquid processed layer(s) can be removed to achieve different mechanical and physical properties, such as compensating for stress induced by device layers (e.g. MOSFET structures) and providing good electrical conduction and adhesion to a die attachment.

The hardening of the material can involve several operations. For example, one operation may be the polymerization of a compound in the precursor material. Depending on the chemistry, crosslinking of the material may be triggered by external stimuli, such as thermal, optical, mechanical, chemical, electrochemical stimuli, and the like. In some embodiments, for example, the precursor material can be polymerized at moderate temperatures, such as from about 60° C. to about 800° C. In some embodiments, the precursor material can be polymerized via the application of a radiation source, such as an infrared source, plank emitter, RF emitter, microwave emitter, UV or blue light emitter, or any emitter of any other suitable electromagnetic radiation. In some embodiments, the precursor can be polymerized by the addition of a polymerization agent or through providing charges through a catalytic, electrochemical, or photolytic process. In some cases, the activation energy can be added by mechanical means through the application of pressure, sound waves, or vibrations. Similar and additional treatments can be applied to other curing mechanisms, such as drying, calcination, sintering, and crystallization. In some embodiments, several mechanisms of curing or solidification are present during a layer treatment process.

In processes where the liquid precursor is applied during the wafer separation process (e.g., after creating a fracture below the boule surface), as described above, thermal energy may be applied to the precursor surface via a radiation source, RF heating, Eddy currents, or injected currents. Such a process may enable the precursor material to shrink or expand either via chemical or physical processes. Through this process, the semiconductor layer separation from the boule or ingot can be achieved by the therewith introduced mechanical stress or via Joule heating of still connected (i.e., not completely laser fractured) areas between the semiconductor layer and the bulk of the semiconductor boule or ingot. In some embodiments, an additional layer, susceptible to the radiation source or conductive to electrical current, may be brought into contact with the surface of the precursor layer. In some embodiments, the semiconductor absorbs most of the energy during the separation process. In some embodiments the liquid precursor layer acts as an acoustic waveguide or acoustic coupler and the energy is supplied via sound.

Once polymerized or annealed at high temperatures, the hardened precursor layer can become a supportive structure for the thin semiconductor layer. In some embodiments, the support structure is similar to a sintered material. In some embodiments, the support structure becomes a ceramic. In some embodiments, the support structure becomes a polymorph crystal structure. The support structure can be tuned to have a coefficient of thermal expansion (CTE) similar to that of the semiconductor material. For example, the difference from the CTE of the semiconductor material to the CTE of the support layer may be about 20% or less, such as about 10% or less, such as about 5% or less, such as about 1% or less.

The CTE of the support layer can be chosen according to the process requirements at elevated temperatures, such as during epitaxial operations, ion implantation, implantation activation, plasma etching, metal diffusion annealing operations, etc. It can be important for the CTE to follow the shape requirements of the process operation. Particular attention can be given to the effect of CTE mismatch induced stress at elevated temperatures, as defect creation and propagation in the thin semiconductor layer should be limited, based on device manufacturing specification. However, through patterning of the support structure that allows for stress relief at less critical areas of the wafer, a certain amount of CTE mismatch can be allowed. In some embodiments, CTE mismatch can even be beneficial, for example, to counteract gravity and acceleration-based or processing-based wafer deformation (e.g., through ion implantation). Another potential advantage of allowing CTE mismatch of at least part of the support layer (e.g., along die boundaries) can be the application of cleavage operations.

Another aspect of the support layer is its electrical conductivity, which can be allowed to be higher than that of the semiconductor, allowing for backside electrical contact at low ohmic losses. In some embodiments, the support layer can exhibit metallic conduction and backside metallization can be omitted, reducing the cost of a device manufacturing operation.

Another aspect of the support layer is its thermal conductivity and adhesion to a printed circuit board, ceramic or metallic substrate, which are typically used in power modules and electronic circuits.

The thickness of the support layer can be about 500 μm or less. Additionally, the purity of the support layer can be high. For example, the precursor material can be free of or have a low concentration of elements that can be mobile in the semiconductors and oxides relevant for device fabrication. If the precursor comprises higher amounts of such elements, they can be removed in subsequent processing operations, such as chemical treatments or high temperature annealing operations.

In other embodiments, instead of using the process to form a support layer on a semiconductor wafer separated from a boule, the process can be used to separate an epitaxial layer from a semiconductor material. Further, it can be used for backside thinning of a workpiece while regaining the backside material as a new surface, which would be bonded to the functional support layer. The process can also be used to separate (i.e., singulate) one or more semiconductor dies from a semiconductor wafer.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, n type material has a majority equilibrium concentration of negatively charged electrons, while p type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation of the scope set forth in the following claims.

Methods disclosed herein may be applied to substrates of various crystalline materials, of both single crystal and polycrystalline varieties. In certain embodiments, methods disclosed herein may utilize cubic, hexagonal, and other crystal structures, and may be directed to crystalline materials having on-axis and off-axis crystallographic orientations. In certain embodiments, methods disclosed herein may be applied to semiconductor materials and/or wide bandgap materials. Example materials include, but are not limited to, silicon, gallium arsenide, and diamond.

In certain embodiments, such methods may utilize single crystal semiconductor materials having hexagonal crystal structure, such as 4H—SiC, 6H—SiC, or Group III nitride materials (e.g., GaN, AlN, InN, InGaN, AlGaN, or AlInGaN). Various illustrative embodiments described hereinafter mention SiC generally or 4H—SiC specifically, but it is to be appreciated that any suitable crystalline material may be used. Among the various SiC polytypes, the 4H—SiC polytype is particularly attractive for power electronic devices due to its high thermal conductivity, wide bandgap, and isotropic electron mobility. Bulk silicon carbide may be grown on-axis (i.e., with no intentional angular deviation from the c-plane thereof, suitable for forming undoped or semi-insulating material) or off-axis (typically departing from a grown axis such as the c-axis by a non-zero angle, typically in a range of from 0.5 to 10 degrees (or a subrange thereof such as 2 to 6 degrees or another subrange), as may be suitable for forming n-doped or highly conductive material).

Certain embodiments herein may use substrates of doped or undoped silicon carbide, such as silicon carbide boules, which may be grown by physical vapor transport (PVT) or other conventional boule fabrication methods. If doped SiC is used, such doping may render the SiC n-type or semi-insulating in character. In certain embodiments, an n-type silicon carbide boule is intentionally doped with nitrogen. In certain embodiments, an n-type silicon carbide boule includes resistivity values within a range of 0.015 to 0.028 Ohm-centimeters. In certain embodiments, a silicon carbide boule may have resistivity values that vary with vertical position, such that different substrate portions (e.g., wafers) have different resistivity values, which may be due to variation in bulk doping levels during boule growth.

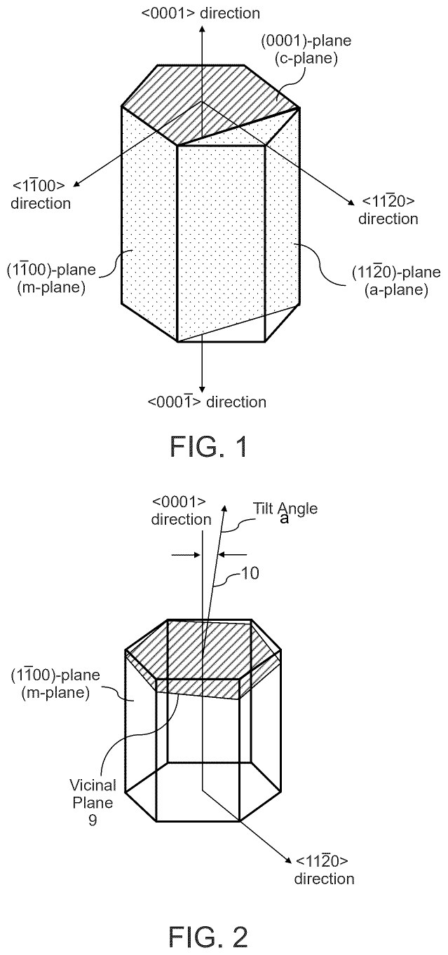

FIG. 1 is a first perspective view crystal plane diagram showing the coordinate system for a hexagonal crystal such as 4H-silicon carbide (“SiC”), in which the c-plane (0001) is perpendicular to both the m-plane (11̅00) and the a-plane (112̅0). The c-plane is perpendicular to the <0001> direction. The m-plane (11̅00) is perpendicular to the <11̅00> direction. The a-plane (112̅0) is perpendicular to the <112̅0> direction. The <0001̅> direction is opposite the <0001> direction.

FIG. 2 is a second perspective view crystal plane diagram for a hexagonal crystal, illustrating a vicinal plane 9 that is non-parallel to the c-plane, wherein a vector 10 (which is normal to the vicinal plane 9) is tilted away from the <0001> direction by a tilt angle α, with the tilt angle α being inclined (slightly) toward the <112̅0> direction.

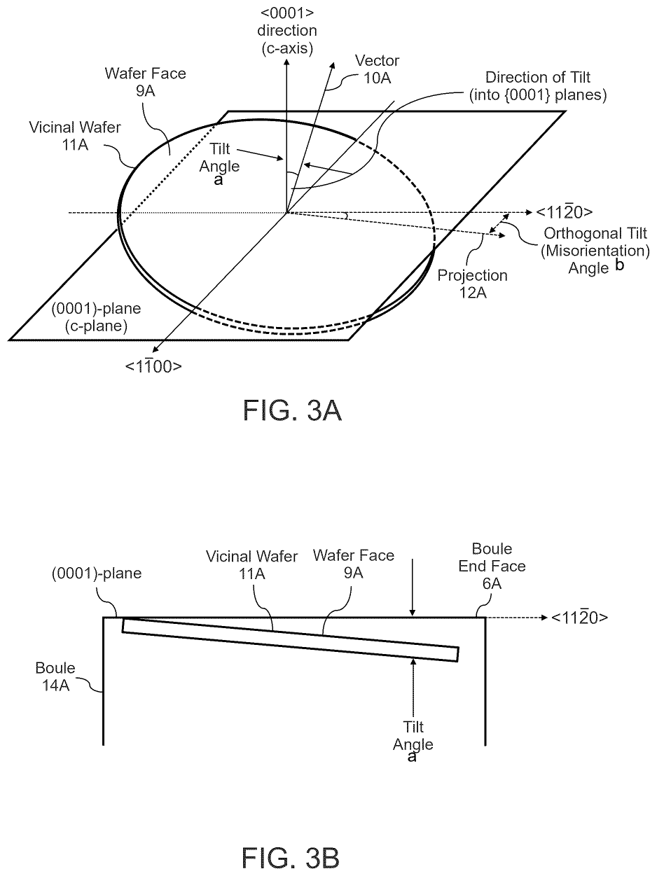

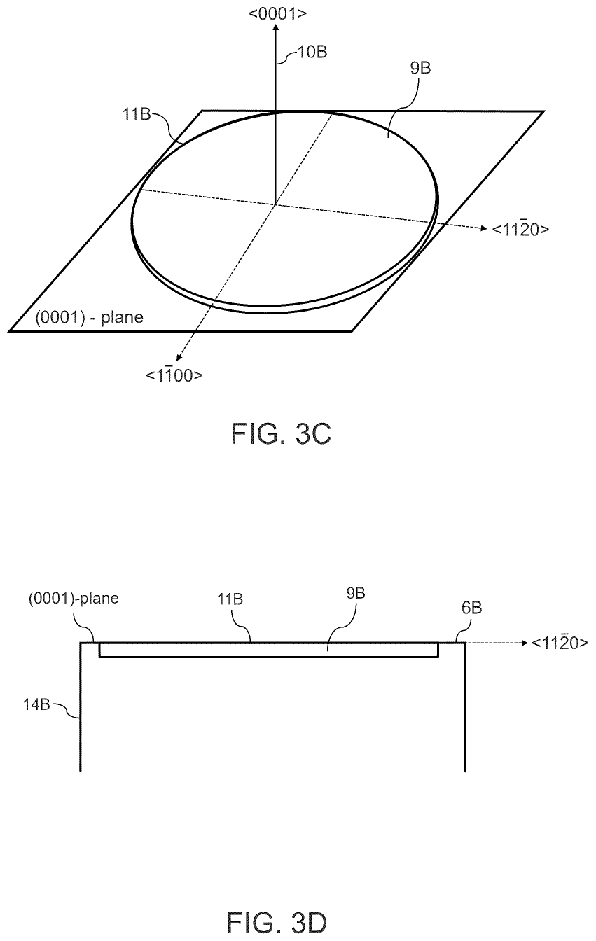

FIG. 3A is a perspective view of a wafer orientation diagram showing orientation of a vicinal wafer 11A relative to the c-plane (0001), in which a vector 10A (which is normal to the wafer face 9A) is tilted away from the <0001> direction by a tilt angle α. An orthogonal tilt (or misorientation angle) β may span between the <112̅0> direction and the projection of vector 10A onto the c-plane.

FIG. 3B is a simplified cross-sectional view of the vicinal wafer 11A superimposed over a portion of a boule 14A (e.g., an on-axis boule having an end face 6A parallel to the (0001) plane) from which the vicinal wafer 11A was defined. FIG. 3B shows that the wafer face 9A of the vicinal wafer 11A is misaligned relative to the (0001) plane by a tilt angle α.

FIG. 3C is a perspective view of wafer orientation diagram showing orientation of an on-axis wafer 11B relative to the c-plane (0001), in which a vector 10B (which is normal to the wafer face 9B) is parallel to the <0001> direction. FIG. 3D is a simplified cross-sectional view of the wafer 11B superimposed over a portion of a boule 14B (e.g., an on-axis boule having an end face 6B parallel to the (0001) plane). FIG. 3D shows that the wafer face 9B of the on axis-wafer 11B is aligned with the (0001) plane.

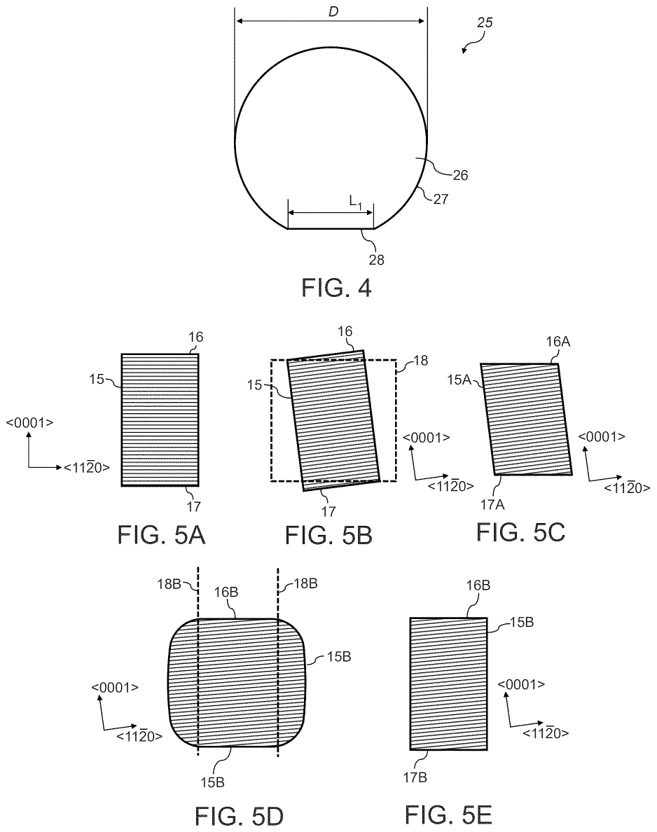

FIG. 4 is a top plan view of an example silicon carbide semiconductor wafer 25 including an upper face 26. The silicon carbide semiconductor wafer 25 may include a surface that is misaligned with (e.g., off-axis at an oblique angle relative to) the c-plane. The silicon carbide semiconductor wafer 25 may be laterally bounded by a generally round edge 27 (having a diameter D) including a primary flat 28 (having a length L₁) that is perpendicular, for instance, to the (112̅0) plane. In some instances, the wafer 25 may include a notch instead of a primary flat.

Methods disclosed herein may be applied to substrates of various crystalline materials, of both single crystal and polycrystalline varieties. In certain embodiments, methods disclosed herein may utilize cubic, hexagonal, and other crystal structures, and may be directed to crystalline materials having on-axis and off-axis crystallographic orientations. In certain embodiments, methods disclosed herein may be applied to semiconductor materials and/or wide bandgap materials. Example materials include, but are not limited to, silicon, gallium arsenide, and diamond.

In certain embodiments, such methods may utilize single crystal semiconductor materials having a hexagonal crystal structure, such as 4H—SiC, 6H—SiC, or Group III-nitride materials (e.g., GaN, AlN, InN, InGaN, AlGaN, or AlInGaN). Various illustrative embodiments described hereinafter mention SiC generally or 4H—SiC specifically, but it is to be appreciated that any suitable crystalline material may be used. Among the various SiC polytypes, the 4H—SiC polytype is particularly attractive for power electronic devices due to its high thermal conductivity, wide bandgap, and isotropic electron mobility. Bulk silicon carbide may be grown on-axis (i.e., with no intentional angular deviation from the c-plane thereof, suitable for forming undoped or semi-insulating material) or off-axis (typically departing from a grown axis such as the c-axis by a non-zero angle, typically in a range of from 0.5 to 10 degrees (or a subrange thereof such as 2 to 6 degrees or another subrange), as may be suitable for forming n-doped or highly conductive material).

Certain embodiments herein may use substrates of doped or undoped silicon carbide, such as silicon carbide boules, which may be grown by physical vapor transport (PVT) or other conventional boule fabrication methods. If doped SiC is used, such doping may render the SiC n-type or semi-insulating in character. In certain embodiments, an n-type silicon carbide boule is intentionally doped with nitrogen. In certain embodiments, an n-type silicon carbide boule includes resistivity values within a range of 0.015 to 0.028 Ohm-centimeters. In certain embodiments, a silicon carbide boule may have resistivity values that vary with vertical position, such that different substrate portions (e.g., wafers) have different resistivity values, which may be due to variation in bulk doping levels during boule growth. In certain embodiments, a silicon carbide boule may have doping levels that vary horizontally, from a higher doping region proximate to a center of the boule to a lower doping level proximate to a lateral edge thereof.

FIGS. 5A and 5C schematically illustrate on-axis and off-axis crystalline substrates in the form of boules that may be utilized with methods disclosed herein. FIG. 5A is a side elevation schematic view of an on-axis boule 15 of crystalline material having first and second end faces 16, 17 that are perpendicular to the c-direction (i.e., <0001> direction for a hexagonal crystal structure material such as 4H—SiC). FIG. 5B is a side elevation schematic view of the boule 15 of FIG. 5A being rotated by four degrees, with a superimposed pattern 18 (shown in dashed lines) for cutting and removing end portions of the boule 15 proximate to the end faces 16, 17. FIG. 5C is a side elevation schematic view of an off-axis boule 15A formed from the boule 15 of FIG. 5B, following removal of end portions to provide new end faces 16A, 17A that are non-perpendicular to the c-direction. Aspects of the present disclosure are applicable to both on-axis boules 15 and/or off-axis boules 15A or other on-axis crystalline materials and/or off-axis crystalline materials.

FIGS. 5D and 5E schematically illustrate off-axis grown boules that may be utilized with methods disclosed herein. FIG. 5D is a side elevation schematic view of an off-axis grown boule 15B of crystalline material (e.g., grown from an off-axis seed material) having first and second end faces 16B and 17B that are non-perpendicular to the c-direction (e.g., <0001> direction for a hexagonal crystal structure material such as 4H—SiC). Portions of the boule 15B may be cut along the superimposed pattern 18B (shown in dashed lines) to provide the off-axis boule 15B shown in FIG. 5E. Off-axis semiconductor wafers may be provided from the off-axis boule 15E by cutting or otherwise removing the wafers from the boule 15B in a manner parallel to the faces 16B, 17B.

Aspects of the present disclosure are directed to providing semiconductor wafers from any suitable boule, such as an on-axis boule, an off-axis boule, an on-axis grown boule, and off-axis grown boule, a boule grown along other directions or axes (e.g., a-axis, c-axis) or other suitable boule.

FIG. 6 illustrates a semiconductor wafer 600 comprising a semiconductor layer (i.e., first layer) 610 and a support layer (i.e., second layer) 620 bonded or otherwise adhered to the semiconductor layer 610. The semiconductor layer 610 is formed from a semiconductor material. In some embodiments, the semiconductor material is a wide-bandgap semiconductor material, such as silicon carbide or a group-III nitride. In some embodiments, the support layer 620 comprises a furan- or ether-based resin and optionally additives. Such additives may include, for example, a glycolate functionalized substance, such as a glycolate functionalized metal or metalloid or a carbide, nitride, or oxide thereof. The glycolate functional groups can be glycolate, diethylene glycolate, glycerolate, or combinations thereof. Suitable metals or metalloids include silicon, tantalum, niobium, tungsten, hafnium, titanium, and/or molybdenum.

In some embodiments, the semiconductor layer can be relatively thin. For example, the thickness of the semiconductor layer (e.g., silicon carbide layer) may be about 100 μm or less, such as about 80 μm or less, such as about 50 μm or less, such as about 30 μm or less, such as about 10 μm or less, such as about 5 μm or less, such as about 3 μm or less, such as about 2 μm or less, such as about 1 μm or less, such as in a range of about 1 μm to about 100 μm, or any sub-range therebetween.

The thickness of the support layer 620 can be any suitable thickness that meets the physical requirements of the wafer. For example, as described above, the thickness may be selected based on handling requirements, thermal requirements, and the like. In some embodiments, the thickness of the support layer 620 can be about 100 μm or more, such as about 200 μm or more, such as about 300 μm or more, such as about 400 μm or more, such as about 500 μm or more, such as about 600 μm or more, such as about 700 μm or more, such as about 800 μm or more. The thickness of the support layer 620 may be about 1000 μm or less, such as about 900 μm or less, such as about 800 μm or less, such as about 700 μm or less, such as about 600 μm or less, such as about 500 μm or less, such as about 400 μm or less, such as about 300 μm or less. In some embodiments, the thickness of the support layer 620 may be in a range of about 50 μm to about 1000 μm, such as about 100 μm to about 800 μm, such as about 200 μm to about 500 μm.

The composition of the support layer 620 may be selected such that it is compatible with the first layer throughout the fabrication process. For example, the support layer 620 may have a coefficient of thermal expansion that is relatively similar to that of the semiconductor material in the semiconductor layer 610 at least in a temperature range relevant to semiconductor processing steps. For typical processes, those can be from about −50° C. to about 2500° C., such as from about 0° C. to about 1700° C., such as from about 16° C. to about 60° C., from about 16° C. to about 120° C., from about 16° C. to about 300° C., from about 90° C. to about 600° C., from about 100° C. to about 1700° C., from about 800° C. to about 1500° C., from about 900° C. to about 1250° C., or from about 800° C. to about 1700° C. CTE control is particularly important in the temperature range where stress can induce material defect creation, defect mobility, and strain. In this regard, a ratio of a coefficient of thermal expansion of the semiconductor layer 610 to a coefficient of thermal expansion (CTE) of the support layer 620 may be from about 0.5 to about 1.5, such as from about 0.6 to about 1.4, such as from about 0.7 to about 1.3, such as from about 0.8 to about 1.2, such as from about 0.9 to about 1.1, such as from about 0.95 to about 1.05 within the temperature ranges described.

As mentioned above, in some embodiments, it may be advantageous for there to be a slight difference in CTE from the semiconductor layer 610 to the support layer 620. In this regard, in some embodiments, the CTE of the support layer 620 may differ by about 2% or more, such as about 5% or more, such as from about 10% or more, from the CTE of the semiconductor layer 610. The difference may be about 50% or less, such as about 40% or less, such as about 30% or less, such as about 20% or less, such as about 15% or less, such as about 10% or less, such as about 5% or less within the temperature ranges described above.

In general, the support layer 620 may have physical properties that make it suitable for use in a semiconductor wafer. For example, the volume resistivity of the support layer 620 may be from about 2×10⁻⁸ Ω·m to about 1×10¹⁰ Ω·m. In some embodiments, for example, the wafer may comprise a layer having a volume resistivity from about 2×10⁻⁸ Ω·m to about 1.5×10⁻⁴ Ω·m. In some embodiments, an additional layer (e.g., a mechanical layer or a patterned high resistivity layer) may be formed having a volume resistivity from about 2×10⁻⁴ Ω·m to about 1×10¹⁰ Ω·m.

The thermal conductivity of the support layer 620 may be from about 500 W/mK or less, such as about 400 W/mK or less, such as about 300 W/mK or less, such as about 200 W/mK or less, such as from about 1 W/mK to about 100 W/mK.

The support layer 620 may be generally free from mobile elements. For example, the concentration of mobile elements may be about 1 ppm or less, such as about 100 ppb or less, such as about 10 ppb or less, such as about 1 ppb or less. Mobile elements may include, for example, metals and ions that can create locally charged regions and would influence drift or stability of electric device characteristics such as MOSFET turn on and turn off thresholds.

In some embodiments, the support layer 620 or parts of the support layer, such as the outer surface or interface to the semiconductor layer or an interface to another conductive layer, may comprise conductive particles. The inclusion of conductive particles may eliminate the need for certain post-production operations, such as backside metallization. In this regard, the support layer 620 may comprise metallic particles therein. In some embodiments, the support layer 620 can comprise tungsten, tantalum, niobium, hafnium, titanium, molybdenum carbide particles or a combination of those. In some embodiments, the support layer comprises low dimensional carbon such as graphene or carbon nano tubes. The concentration of metallic particles or low dimensional carbon may be from about 1 wt. % to about 95 wt. %, such as about 1 wt. % to about 90 wt. %, such as about 1 wt. % to about 50 wt. %, such as about 1 wt. % to about 20 wt. %, or from about 20 wt. % to about 90 wt. %, such as about 20 wt. % to about 50 wt. % or about 50 wt. % to about 90 wt. %.

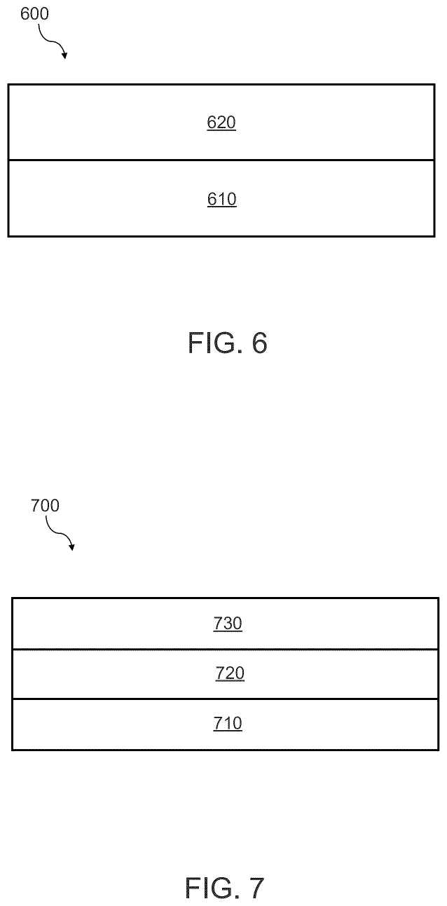

In some embodiments, the semiconductor wafer may have more than two layers. For example, FIG. 7 illustrates a semiconductor wafer 700 comprising a semiconductor layer (i.e., first layer) 710, a support layer (i.e., second layer) 720 bonded or otherwise adhered to the semiconductor layer 710, and a top layer (i.e., third layer) 730 bonded or otherwise adhered to the support layer 720. The semiconductor layer 710 may have any of the properties described above for semiconductor layer 610 described with reference to FIG. 6. Similarly, support layer 720 and top layer 730 may have any of the properties described above for support layer 620 described with reference to FIG. 6.

In some embodiments, support layer 720 and top layer 730 can have complimentary properties. For example, the support layer 720 may be formed from a composition selected to have a similar CTE to that of the semiconductor layer 710, while a second layer may be formed from a composition selected to provide a low resistivity (e.g., to the semiconductor layer or to eliminate the need for backside metallization). For example, in some embodiments, a ratio of a coefficient of thermal expansion of the semiconductor layer 710 to a coefficient of thermal expansion (CTE) of the support layer 720 may be from about 0.5 to about 1.5, such as from about 0.6 to about 1.4, such as from about 0.7 to about 1.3, such as from about 0.8 to about 1.2, such as from about 0.9 to about 1.1, such as from about 0.95 to about 1.05. The top layer 730 can have a volume resistivity of about 1.5×10⁻⁴ Ω·m X or less, such as about 1×10⁻⁵ Ω·m or less, such as about 1×10⁻⁶ Ω·m or less, such as from about 2×10⁻⁸ Ω·m to about 1×10⁻⁷ Ω·m. In this regard, the top layer 730 may comprise conductive particles, such as metallic particles, therein. In some embodiments, the top layer 730 can comprise tungsten carbide particles. The concentration of metallic particles may be as described above, such as from about 1 wt. % to about 95 wt. %.

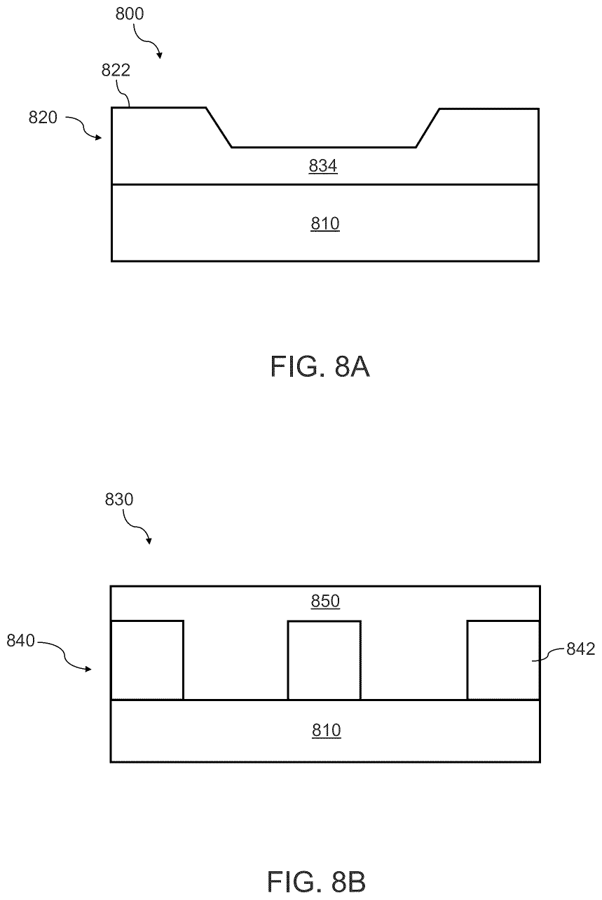

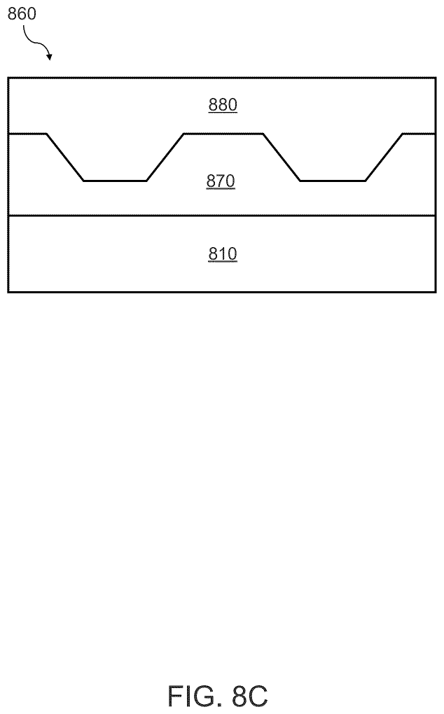

In some embodiments, the support layer and/or top layer (if included) can have non-uniform thicknesses. For example, FIG. 8A illustrates a semiconductor wafer 800 comprising a semiconductor layer 810 and a support layer 820 having a first portion 822 having a first thickness and a second portion 834 having a second thickness. The first thickness is greater than the second thickness. The ratio of the first thickness to the second thickness may be about 1.1 or more, such as about 1.2 or more, such as about 1.3 or more, such as about 1.5 or more, such as about 1.7 or more, such as about 2 or more, such as about 2.5 or more, such as about 3 or more, such as about 4 or more, such as about 5 or more. The ratio of the first thickness to the second thickness may be about 100 or less, such as about 70 or less, such as about 50 or less, such as about 30 or less, such as about 20 or less, such as about 10 or less, such as about 5 or less, such as about 3 or less, such as about 2 or less, such as about 1.5 or less.

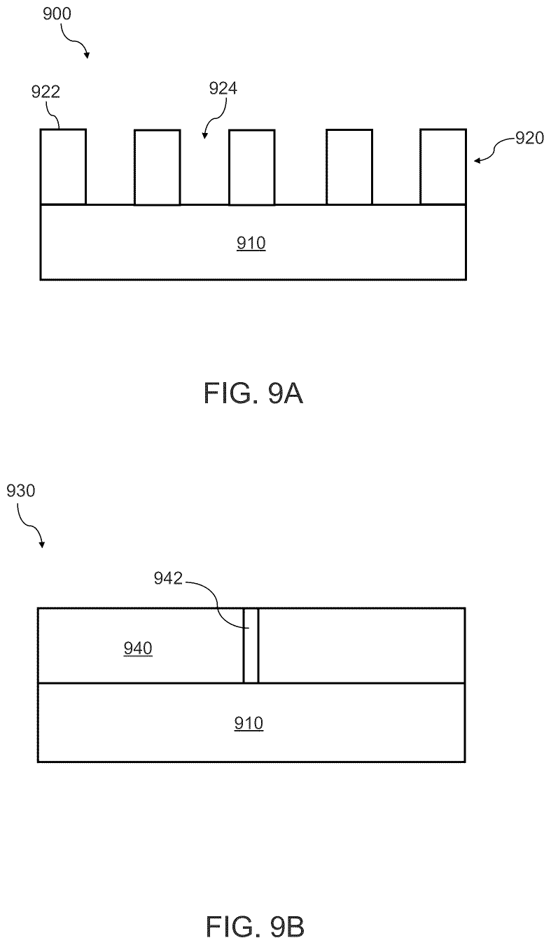

It should be understood that the support layer 820 may be any suitable shape and is not limited to that shown in FIG. 8A. For example, in some embodiments, the thickness may be greater in certain areas of the semiconductor wafer. In some embodiments, the thickness profile may be selected such that certain areas of the support layer shrink or expand more than other areas under certain conditions (e.g., temperature or under irradiation). For example, it may be desirable for certain areas to shrink or expand to aid in separating the wafer from a boule at a fracture layer. In some embodiments, the thickness profile may be tailored based on thermal conductivity and heat transfer requirements in certain areas of the wafer. In some embodiments, it may be desirable to have relatively thin portions of the support layer in sections between dies that will be cut from the wafer (e.g., the “streets”) to aid in die singulation. It should also be understood that in three layer wafers, either or both of the support layer and the top layer may have non-uniform thicknesses. In some embodiments, the support layer may have areas with a thickness of 0. For example, as shown in FIG. 9A, the support layer may have gaps resulting in uncovered areas. In some embodiments, a second layer may be formed above the support layer that fills in such gaps and provides a planar surface. For example, FIG. 8B shows a semiconductor wafer 830 having a semiconductor layer 810, a support layer 840 comprising sections 842 of material having with one or more gaps, and a top layer 850 filling in the gaps in layer 840 and providing the semiconductor wafer 830 with a flat top surface. Similarly, FIG. 8C shows a semiconductor wafer 860 having a semiconductor layer 810, a support layer 870 comprising sections having a first thickness and sections having a second thickness less than the first thickness, and a top layer 880 filling in the low portions (i.e., the portions above the sections of the support layer having the lower thickness) in layer 870 and providing the semiconductor wafer 860 with a flat top surface.

As shown in the embodiments of FIG. 8B, in some embodiments, the support layer and/or top layer (if present) may be patterned. As another example, FIG. 9A shows a semiconductor wafer 900 having a semiconductor layer 910 and a patterned support layer 920. As shown, the support layer is selectively applied or removed such that there are sections 922 that comprise a support material and sections 924 that do not. The patterned may be selected for similar reasons as described above with respect to support layers having non-uniform thicknesses.

As described in further detail below, the non-uniform thickness profile of the support layer (e.g., 820 in FIGS. 8A, 870 in FIG. 8C) or the patterned support layer (e.g., 840 in FIGS. 8B, 920 in FIG. 9A) may be formed by selectively applying a liquid precursor, selectively curing the liquid precursor, or selectively removing portions of the cured resin to obtain the desired pattern. For three or more layer wafers, in some embodiments, the support layer (i.e., second layer) has a uniform thickness and the top layer (i.e., third layer) is patterned and/or has a non-uniform thickness. In other embodiments, both the support layer and the top layer may be patterned and/or have a non-uniform thickness. The pattern or thickness profiles of the support layer and the top layer may be the same or different.

In some embodiments, as shown in FIG. 9B, a semiconductor wafer 930 may comprise one or more vias 942, which can provide electrical and/or thermal conductivity between the semiconductor material layer 910 and the backside of the support layer 940. The via(s) 942 may be a channel passing through the support layer 940 which may be filled or coated with a metal to provide the desired electrical/thermal conductivity. When the semiconductor wafer comprises more than one additional layer (e.g., two liquid processed layers) the via(s) can pass through the support layer and the one or more additional layers or it can pass through the support layer only, connecting the semiconductor layer to the one or more additional layers. Further, although FIG. 9B shows the via(s) extending only to the interface between the semiconductor layer and the support layer, it should be understood that the via may extend through the semiconductor layer to the outer surface thereof, or it can extend to an intermediate portion of the semiconductor layer.

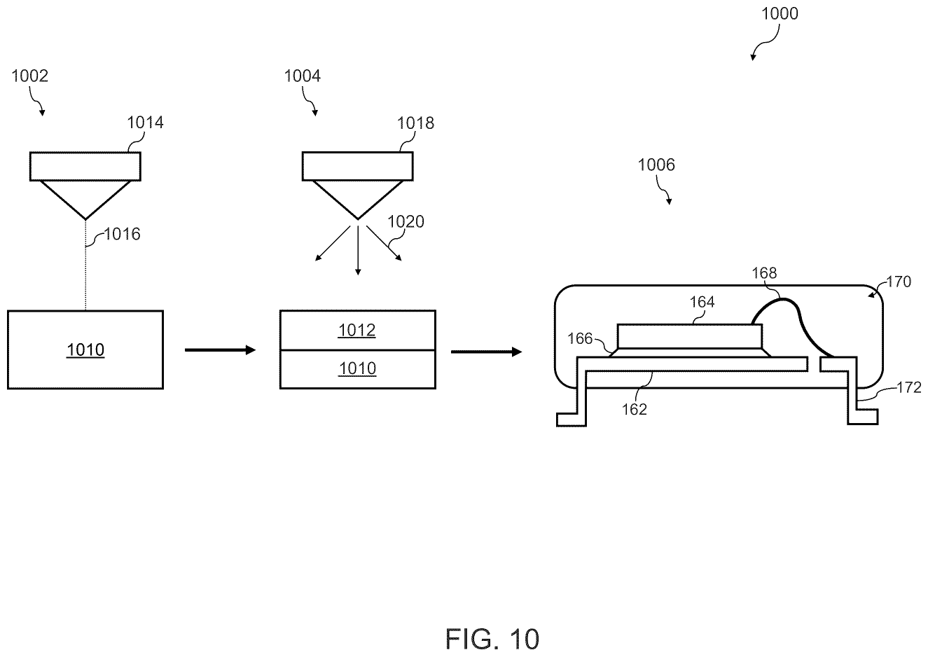

FIG. 10 depicts an overview of an example method 1000 according to example embodiments of the present disclosure. FIG. 10 is intended to represent structures for identification and description and is not intended to represent the structures to physical scale. The method 1000 includes operations illustrated in a particular order for purposes of illustration and discussion. Those of ordinary skill in the art, using the disclosures provided herein, will understand that the various steps or operations of the method may be adapted, rearranged, omitted, include steps not illustrated, and/or modified in various ways without deviating from the scope of the present disclosure.

At 1002, the method 1000 may include applying a liquid precursor 1016 from a liquid processing apparatus 1014 to a semiconductor material 1010. The semiconductor material 101 can be a relatively thin layer of material. For example, the thickness of the semiconductor layer (e.g., silicon carbide layer) may be about 100 μm or less, such as about 80 μm or less, such as about 50 μm or less, such as about 30 μm or less, such as about 10 μm or less, such as about 5 μm or less, such as about 3 μm or less, such as about 2 μm or less, such as about 1 μm or less.

The liquid precursor may be applied by any suitable liquid processing method. For example, the liquid precursor may be applied by spin-coating, slip casting, doctor blading, dipping, screen printing, stamping, spray coating, brushing or rolling, condensation, electrostatic deposition, lamination, and the like. The liquid precursor may also be partially cured prior to deposition. For example, the liquid can become a thermoplastic after partial curing. That thermoplastic can be processed onto the surface at elevated temperature through printing, rolling, lamination, etc.

In some embodiments, the liquid precursor application can involve the control of the ambient atmosphere, pressure, and/or temperature depending on the liquid precursor composition. In some embodiments, for example, temperature control is achieved via a radiation source or via a temperature-controlled wafer fixture or chuck.

In some embodiments, the liquid precursor is a thermoplastic or a partially cured liquid precursor. Similarly, the liquid precursor application can involve the control of the ambient atmosphere, pressure, and/or temperature depending on the liquid precursor composition.

In some embodiments, the top surface of the semiconductor boule may be prepared before the liquid precursor application. For example, the surface may be conditioned to obtain a desired surface roughness.

In some embodiments, the liquid may be applied in a desired pattern. For example, in some embodiments, a patterning of the precursor material can be employed to influence wafer shape behavior. For example, patterning can be employed to change stiffness, friability, or plasticity in certain regions, at ambient conditions or conditions (e.g., temperature) of layer processing operations such as epitaxy or ion implantation. In other embodiments, the liquid may be applied in a uniform thickness. Patterning of the additional layer can also be employed to influence mechanical properties for further processing such as processing wafer dimensions, die dimensions, lithography stepper ranges, etc.

The liquid precursor 1016 generally comprises a furan- or ether-based curable prepolymer, optionally additives and optionally a solvent. In some embodiments, the liquid precursor comprises functional components to adjust the properties of the material before and/or after hardening. In some embodiments, for example, the functional components can include glycolate functionalized metals, metalloids, or their silicides, carbides, nitrides, or oxides, or low dimensional carbon materials. In some embodiments, the functional groups comprise glycolate, diethylene glycolate, or glycerolate. In some embodiments, the functional compounds can include silicon carbide, tantalum, niobium, tungsten, hafnium, titanium, and/or molybdenum or their silicides, carbides, nitrides, or oxides.

In some embodiments, the liquid precursor may comprise a solvent. The solvent can be selected or modified to have suitable wettability, rheology, evaporation rate, or curing properties. In some embodiments, the solvent is selected or modified based on desired shelf life, storage conditions, or environmental safety or health considerations.

At 1004, the method 1000 may include curing the liquid precursor to obtain a solid resin layer 1012. In some embodiments, such as that shown by FIG. 10, curing can include irradiating or heating the liquid precursor using an energy source 1018 that applies energy 1020 in the form of heat or radiation to the liquid precursor. The radiation source may include an infrared source, plank emitter, RF emitter, microwave emitter, UV or blue light emitter, or any emitter of any other suitable electromagnetic radiation. In some embodiments the liquid precursor is cured by heating using any suitable heating source. In some embodiments, for example, the precursor material can be polymerized at moderate temperatures, such as from about 60° C. to about 800° C.

While FIG. 10 shows curing by an incoherent radiation source, it should be understood that in some embodiments, the liquid may be selectively cured in a desired pattern, for example, by directing a localized or coherent energy source at the liquid precursor in the desired pattern to induce selective curing.

Alternatively, in other embodiments, curing (i.e., crosslinking, calcination, sintering, crystallization, etc.) of the liquid precursor may be triggered by optical, mechanical, chemical, electrochemical stimuli, and the like. In some embodiments, for example, the precursor can be polymerized by the addition of a polymerization agent or through providing charges through a catalytic, electrochemical, or photolytic process. In some cases, the activation energy can be added by mechanical means through the application of pressure, sound waves, or vibrations.

After curing, the resulting semiconductor wafer may be subjected to various processing operations. For example, in some embodiments, the cured layer may be thinned or selectively removed to create a pattern or desired thickness profile. Additionally, the wafer may undergo further processing operations such as etching, electrochemical etching, laser ablation, grinding, polishing, lapping, CMP, and the like. The wafer may undergo further semiconductor fabrication operations, such as epitaxy operations, etching, dicing, and the like, as is known in the art, to form one or more semiconductor die from the wafer.

At 1006, method 1000 may include forming a semiconductor device package comprising one or more semiconductor die produced from the semiconductor wafer. The semiconductor device package may include one or more semiconductor die. The semiconductor device package may be included in a power semiconductor device assembly. For example, as shown in FIG. 10, the semiconductor package may include a conductive submount 162 (e.g., a patterned conductive substrate, lead frame, clip structure or other power substrate) on which a semiconductor die 164 comprising one or more power devices (e.g., transistors, diodes, etc.) is attached using a die-attach material 166. The die-attach material 166 may provide a thermal, mechanical, and electrical connection between the semiconductor die 164 and the conductive submount 162. In some examples, the semiconductor die 164 may also be connected to the conductive submount 162 using wire bonds 168. An encapsulating material 170 (e.g., epoxy mold compound (EMC)) may fill the space around the semiconductor die 164 and the submount 162, thereby forming a housing. The semiconductor package may further include one or more electrical leads 172 that extend outward from the housing (e.g., outward from the encapsulating material 170).

The semiconductor package may include one or more metallization structures. More particularly, the semiconductor die 164 may include one or more metallization structures, such as bonding pads. The bonding pads may be coupled to the one or more electrical leads 172 using the wire bonds 168 or may be bonded to a contact or support structure metal directly. The wire bonds 168 may be aluminum and/or copper. The wire bonds 168 may have a thickness of about 15 mil to about 20 mil (e.g., about 381 μm to about 508 μm). The bonding pads may have a thickness, for instance, of about 4 μm or less. A backside metallization layer (or a layer comprising conductive material as described herein) on the semiconductor die 164 may be coupled to the submount 162 (e.g., lead frame) using, for instance, the die-attach material 166. The encapsulating material 170 may encapsulate the semiconductor die 164, including its metallization structures, wire bonds 168, submount 162, and other portions of the semiconductor package. In some examples, the encapsulating material 170 may directly contact the metallization structures (e.g., bonding pads, backside metallization layer, etc.) of the semiconductor package.

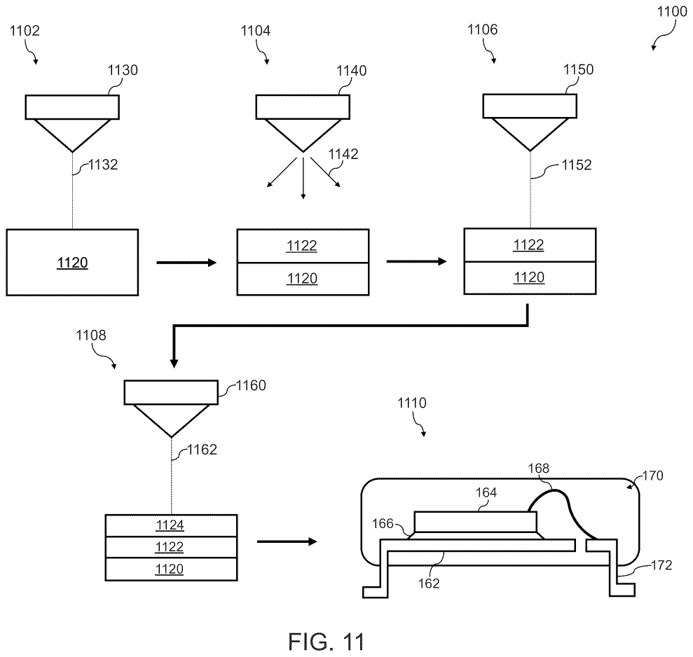

FIG. 11 depicts an overview of an example method 1100 according to example embodiments of the present disclosure. FIG. 11 is intended to represent structures for identification and description and is not intended to represent the structures to physical scale. The method 1100 includes operations illustrated in a particular order for purposes of illustration and discussion. Those of ordinary skill in the art, using the disclosures provided herein, will understand that the various steps or operations of the method may be adapted, rearranged, omitted, include steps not illustrated, and/or modified in various ways without deviating from the scope of the present disclosure.

Method 1100 can be used to produce a three layer semiconductor wafer. Operations 1102 and 1104 may be conducted in the same manner as described above for operations 1002 and 1004 of method 1000. For example, at 1102, the method 1100 may include applying a liquid precursor material 1132 to the surface of a semiconductor material 1120 using a liquid processing apparatus 1130. At 1104, the liquid precursor can be cured into a solid layer 1122 by any suitable method. For example, it can be cured by applying radiation 1142 from a radiation source 1140.

At 1106, the method 1100 may include applying a second liquid precursor material 1152 from a second liquid processing apparatus 1150 to the surface of the solid layer 1122. The second liquid precursor material may have the same composition as the liquid precursor used to form layer 1122. Alternatively, the second liquid precursor may have a different composition from the first liquid precursor. For example, it may comprise different additives. In one embodiment, for example, the first liquid precursor does not comprise conductive particles, and the second liquid precursor comprises conductive particles. In one embodiment, the first liquid precursor comprises conductive particles, and the second liquid precursor does not comprise conductive particles.

The second liquid processing apparatus 1150 may be the same or different from the first liquid processing apparatus 1130.

At 1108, the method 1100 may include at least partially curing the second liquid precursor to form a solid top layer (i.e., third layer) 1124. As shown in FIG. 11, the top layer may be cured by applying a liquid curing or crosslinking agent 1162 from a third liquid processing apparatus 1160. The third liquid processing apparatus may be the same or different from the first liquid processing apparatus 1130 and/or the second liquid processing apparatus 1150. The liquid curing or crosslinking agent can include any suitable chemical for curing the second liquid precursor. Such crosslinking agents are known in the art for various curable liquid resins.

It should be understood that while FIG. 11 illustrates curing by applying radiation 1142 in operation 1104 and by applying a liquid crosslinking agent 1162 in operation 1108, any suitable curing method may be used at each operation. For example, as described above, curing can include thermal, optical, mechanical, chemical, electrochemical stimuli, and the like.

As described above with respect to FIG. 10, the semiconductor wafer may undergo a series of semiconductor processing operations, such as etching, electrochemical etching, laser ablation, grinding, polishing, lapping, CMP, epitaxy operations, etching, dicing, and the like to form one or more semiconductor dies therefrom.

At 1110, method 1100 may include forming a semiconductor device package comprising one or more semiconductor die produced from the semiconductor wafer. The resulting semiconductor device package can be similar to that described above with respect to FIG. 10, except that the die 164 is formed from the three layer wafer instead of a two layer wafer.

It should also be understood that, if desired, more than three layers can form the semiconductor wafer by repeating similar operations to forming the second layer and the third layer. Also, not all layers formed may be present in the finished die or device. For example, in some embodiments, a semiconductor wafer with a first, second, or more layers of liquid processed material can be optimized to provide mechanical and physical properties through a series of semiconductor process steps. At a later step, part of the liquid processed layer(s) can be removed to achieve different mechanical and physical properties, such as compensating for stress induced by device layers (e.g. MOSFET structures) and providing good electrical conduction and adhesion to a die attachment.

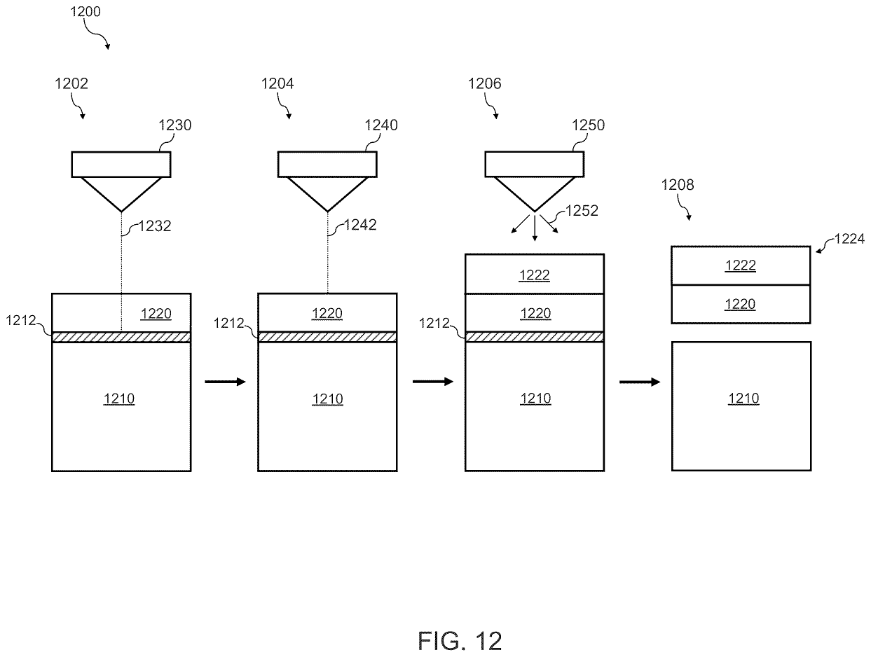

FIG. 12 depicts an overview of an example method 1200 according to example embodiments of the present disclosure. FIG. 12 is intended to represent structures for identification and description and is not intended to represent the structures to physical scale. The method 1200 includes operations illustrated in a particular order for purposes of illustration and discussion. Those of ordinary skill in the art, using the disclosures provided herein, will understand that the various steps or operations of the method may be adapted, rearranged, omitted, include steps not illustrated, and/or modified in various ways without deviating from the scope of the present disclosure.

At 1202, the method 1200 may include providing a semiconductor boule 1210 with a modified subsurface layer (e.g., fracture layer) 1212. The modified subsurface layer 1212 may be the result of an induced subsurface damage process performed on the semiconductor boule 1210. The induced subsurface damage process may be a laser-based removal process or other induced subsurface damage process (e.g., ion implantation induced subsurface damage process). For instance, in some examples, one or more damage-inducing energy sources 1230 (e.g., a radiation source or an ion beam) may be operated to provide a damage-inducing emission of radiation or ions 1232 to induce a modified subsurface layer 1212 in the semiconductor boule 1210.

In some embodiments, the modified subsurface layer 1212 is formed by creating an induced damage region that is generally parallel to the upper surface of the semiconductor boule, or the implementation of a subsurface layer below the upper surface of the semiconductor boule 1210 at a targeted depth. The induced damage region may be created by one or more passes of an emission of radiation, such as the emission of a laser, to induce subsurface damage at a target depth below the upper surface of the boule.

In some embodiments, the modified subsurface layer may be created by ion (or other species) implantation. For example, in an ion implantation process, impurity (e.g., dopant) ions can be accelerated to a high energy and directed towards the semiconductor surface by an ion beam. The implants penetrate the surface and come to rest at a depth dependent on the energy and angle with respect to the crystal orientation.

In some examples, the damage inducing radiation source may be one or more laser sources that provide the emission of the radiation to the modified subsurface layer of the boule. In some examples, the laser treatment process may be conducted by one or more laser sources in the infrared, visible, and/or the ultraviolet range of the electromagnetic spectrum. In some examples, the one or more laser sources may be operated in continuous or pulsed modes. In some examples, the one or more radiation sources may be operable with an average power from about 1 to about 500 W, such as about 1 to about 100 W, such as about 5 W to about 30 KW, such as about 200 W to about 300 W. In some examples, the one or more radiation sources may be operable with continuous power supplied or with a frequency of about 0.1 kHz to about 100 MHz or higher (e.g., 10 W at 100 MHz). The one or more radiation sources may include coherent radiation sources, such as electric gas discharge lasers (e.g., a gas discharge radiation source where a fraction of emitted electromagnetic radiation is amplified), metal vapor lasers (e.g., a copper vapor lasing medium), yttrium aluminum garnet (YAG) lasers including doped YAG lasers (e.g., Nd:YAG or Yb:YAG), fiber lasers (e.g., ytterbium doped glass), disc lasers, or rod lasers (e.g., chromium doped chrysoberyl), diode lasers (e.g., GaN, GaAs, and/or diode lasers comprising InP). The one or more radiation sources may be operated in a manner that allows nonlinear frequency conversion (e.g., frequency doubling or tripling) to meet absorption and/or optical requirements of the workpiece. The one or more radiation sources may additionally include optical means to modify the angle of incidence of the emission of radiation relative to the surface of the boule, or otherwise modify the emission of radiation, which may produce tuned irradiance profiles of the emission along a propagation distance.

In some examples, the radiation source may be one or more gas discharge sources that provide the emission of the radiation to the modified subsurface layer of the boule. The gas discharge treatment process may include exposure to electromagnetic radiation generated by low or high pressure ionization of xenon, carbon dioxide, mercury, or sodium in a gaseous form.

In some examples, the radiation source may be one or more incandescent radiation sources that provide the emission of the radiation to the modified subsurface layer of the boule. The incandescent radiation treatment process may include a filament-based radiation source and/or a halogen cycle (e.g., a halogen tungsten lamp). The incandescent radiation source may be operable in a range of about 5 watts to about 30,000 watts, such as about 5 watts to about 500 watts, or about 0.5 kilowatts to about 20 kilowatts. The incandescent radiation treatment process may include optical elements to tune optical energy (e.g., optical elements that steer, shape, or focus radiation such as lenses, mirrors, collimators, etc.) from the incandescent radiation source.

In some examples, the radiation source may be one or more electroluminescence emitters that provide the emission of the radiation to the modified subsurface layer of the boule. The electroluminescence emitter treatment process may include one or more light emitting diodes (LEDs) operable in a range of about 5 watts to about 30,000 watts, such as about 5 watts to about 500 watts, or about 0.5 kilowatts to about 30 kilowatts. The electroluminescence radiation treatment process may include optical elements to tune optical energy (e.g., optical elements that steer, shape, or focus radiation such as lenses, mirrors, collimators, etc.) from the incandescent radiation source.

In some examples, the radiation source may be one or more electronic or magnetic oscillators that provide the emission of the radiation to the modified subsurface layer of the boule. The electronic or magnetic treatment process may include a high-vacuum tube operable to generate and/or amplify electromagnetic radiation resulting from interactions of electrons within the tube. The electromagnetic radiation may encompass radio wavelengths, terahertz wavelengths, or microwave wavelengths, such as electromagnetic radiation that ranges from about 0.1 millimeters to about 1 meter.

In some examples, the radiation source may be one or more free electron resonators that provide the emission of the radiation to the modified subsurface layer of the boule. The free electron resonator treatment process may include treatment with coherent radiation resulting from electron beam propagation through a magnetic field.

In some examples, the radiation source may be one or more x-ray emitters that provide the emission of the radiation to the modified subsurface layer of the boule. The x-ray emitter treatment process may include the generation of electromagnetic radiation (e.g., x-rays) resulting from the bombardment of high-speed electrons with a target material. The resulting electromagnetic radiation may be a result of electrons bound with the target material falling into lower energy states.

In some examples, the radiation source may be one or more bremsstrahlung emitters that provide the emission of the radiation to the modified subsurface layer of the boule. The bremsstrahlung treatment process may include the generation of electromagnetic radiation (e.g., x-rays) resulting from an abrupt velocity change due to a collision or other scattering event of an electron interacting with an atomic nucleus.

The modified subsurface layer 1212 may comprise voids, dopants, crystallographic 1d or 2d defects, broken bonds, recrystallized material, or amorphized material as a result of the irradiation or ion implantation process. Above the modified subsurface layer is a relatively undamaged layer of semiconductor material 1220 that will form the semiconductor layer of the semiconductor wafer resulting from the process.

Due to the support layer to be added on the semiconductor material layer 1220, the modified subsurface layer may be formed at a shallower depth than usual. For example, the depth of the modified subsurface layer 1212 may be about 100 μm or less, such as about 80 μm or less, such as about 50 μm or less, such as about 30 μm or less, such as about 10 μm or less, such as about 5 μm or less, such as about 3 μm or less, such as about 2 μm or less, such as about 1 μm or less below the top surface of the semiconductor boule 1210.

Referring to FIG. 12 at 1204, the method 1200 may include applying a curable liquid precursor resin 1242 to the top surface of the boule 1210 above the modified subsurface layer 1212 via liquid processing apparatus 1240. The application of the liquid precursor can be by any method described above, for example, as described in operation 1002 of method 1000 (FIG. 10).

At 1206, the method 1200 may include curing the liquid precursor to form a solid layer 1222 bonded to the top surface of the semiconductor layer 1220. The curing process can be by any method described above, for example, as described in operation 1004 of method 1000 (FIG. 10).

At 1208, the method 1200 may include separating a semiconductor wafer 1224 from the remaining portion of the boule 1210 at the interface layer. In some embodiments, the separation may occur from the curing process alone, without requiring any further active operations. For example, curing may cause the precursor material to shrink or expand in a different way than the semiconductor material either via chemical or physical processes. For example, compressive or tensile strain may be applied when the precursor layer does not expand much while the semiconductor layer does or vice versa. Through this process, the semiconductor layer separation from the boule or ingot can be achieved by the therewith introduced mechanical stress or, in under application of electrical stimuli, via Joule heating of still connected (i.e., not completely laser fractured) areas between the semiconductor layer and the bulk of the semiconductor boule or ingot. In some embodiments, an additional layer, susceptible to the radiation source or conductive to electrical current, may be brought into contact with the surface of the precursor layer.

In other embodiments, an additional operation may be required to separate the wafer from the boule at the modified subsurface layer 1212. For example, in some embodiments, separation can be triggered by heating. In other embodiments, separation may include a mechanical fracturing process, ultrasonic fracturing process, or other fracturing process to fracture and separate the semiconductor wafer 1224 from the remaining portion of the semiconductor boule 1210. In some embodiments, for example, the uncured, partially cured, or fully cured precursor layer enables acoustic or ultrasonic fracturing by functioning as a waveguide or acoustic coupling layer. In some embodiments, a wire saw may be used to separate the wafer 1224 from the boule 1210. If a wire saw is used, the formation of the modified subsurface layer 1212 can be omitted.

The process can involve the application of one or more subsequent layers after the separation to re-adjust thermal and mechanical properties of the wafer after the first layer was optimized for properties relevant for the separation process. In this regard, the process can also include application of a second or additional layer that acts as separation process layer and that will be thinned or removed after separation to readjust thermal, mechanical, and geometric properties of the wafer.

In some embodiments, the support layer 1222 is only partially cured in operation 1206 and then is fully hardened after wafer separation at 1208. For example, partial curing may be triggered by heating the liquid precursor material to a temperature from about 60° C. to about 200° C. The partial curing operation can solidify the resin without fully hardening it. Following wafer separation, the wafer may be subjected to an annealing operation at a higher temperature than the partial cuing temperature, for example, up to about 800° C., to fully harden the resin.

Further processing may be performed on either the semiconductor wafer 1224 or the remaining portion of the boule 1210. Further processing operations (e.g., etching, electrochemical etching, laser ablation, grinding, polishing, lapping, CMP, and the like) may remove portions of the exposed surface and/or provide a smoother surface suitable for later fabrication operations, such as surface implantation, formation of epitaxial layers, metallization, etc. The finished semiconductor wafer may then be diced and packaged to be used in power electronic devices.

By processing the exposed surface of the remainder of the boule 1210, the remainder of the boule 1210 may be suitable to be reused for subsequent wafer separation processes.

In any of the methods described herein, the boule and resulting semiconductor wafer may have a relatively large diameter, such as from about 150 mm to about 310 mm.

Because the semiconductor layer can be made thinner than conventional wafers due to the mechanical strength added by the support layer, and due to the ability to pattern the support layer as desired, the die singulation process can be simplified.

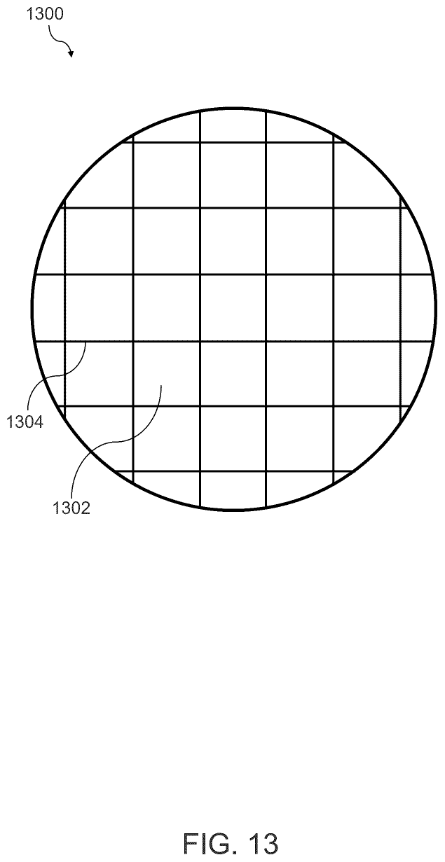

FIG. 13 shows a top view of an example semiconductor wafer 1300 that can be diced along lines (e.g., streets) 1304 to produce a plurality of semiconductor dies 1302. The dies can then be packaged for use in semiconductor devices. In some embodiments, the wafer can be cut along lines 1304 using a circular saw, a scribe-and-break process, laser dicing, laser ablation dicing, plasma dicing, or the like. In some embodiments, the support layer can be patterned so as to be thinner or absent in the lines (e.g., street areas) 1304. In some embodiments, the wafer is cut along the streets 1304 using only a breaker, as the semiconductor (e.g., silicon carbide) layer is thin enough that a saw is not necessary, and the pattern of the support layer can serve as a scribe pattern, eliminating the need for an additional scribe process.

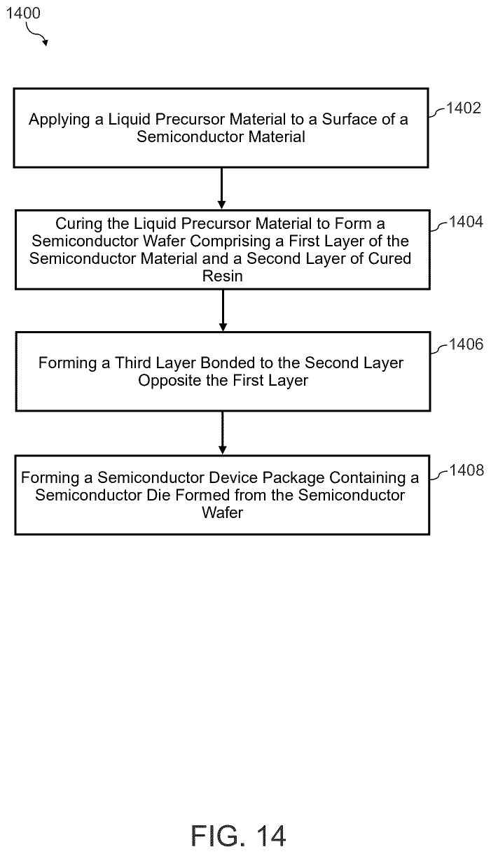

FIG. 14 depicts a flow chart diagram of an example method 1400 according to aspects of the present disclosure. The method 1400 depicts operations in a particular order for purposes of illustration and discussion. Those of ordinary skill in the art, using the disclosures provided herein, will understand that the various steps or operations of the method may be adapted, rearranged, omitted, include steps not illustrated, and/or modified in various ways without deviating from the scope of the present disclosure.

At 1402, the method 1400 may include applying a liquid precursor material to a surface of a semiconductor material. In some embodiments, the semiconductor material may include silicon carbide or a group III-nitride. In some embodiments the semiconductor material may be relatively thin. For example, in some embodiments, the thickness of the semiconductor material may be about 100 μm or less, such as about 80 μm or less, such as about 50 μm or less, such as about 30 μm or less, such as about 10 μm or less, such as about 5 μm or less, such as about 3 μm or less, such as about 2 μm or less, such as about 1 μm or less. In other embodiments, the semiconductor material may be a boule having a much greater thickness from which a thinner wafer will be separated from.

As described above, the liquid precursor material may comprise a furan- or ether-based curable resin optionally comprising a solvent and/or additives. Additives may include glycolate functionalized substances (e.g., a metal or metalloid or a carbide, nitride, or oxide thereof) comprising functional groups such as glycolate, diethylene glycolate, and/or glycerolate functional groups.

Application of the liquid precursor material may be by spin-coating, slip casting, doctor blading, dipping, screen printing, stamping, spray coating, brushing, rolling, condensing, electrostatic deposition, or laminating the precursor material on the surface of the semiconductor material. The liquid precursor may also be partially cured prior to deposition. For example, the liquid can become a thermoplastic after partial curing. That thermoplastic can be processed onto the surface at elevated temperature through printing, rolling, lamination, etc. In some embodiments, the liquid precursor material is applied to the surface of the semiconductor material in a non-uniform pattern. Optionally, the liquid precursor material is applied uniformly to the surface of the semiconductor material and then treated to form a layer of non-uniform thickness. Such treatment may occur before or after curing, or after partially curing but before fully curing, the resin.

At 1404, the method 1400 may include curing the liquid precursor material to form a semiconductor wafer comprising a first layer of the semiconductor material and a second layer of cured resin. As described above, curing may include heating the liquid precursor material, such as heating the liquid precursor material to a temperature from about 60° C. to about 800° C. In some embodiments, curing can include applying a radiation source, such as an infrared source, a plank emitter, an RF emitter, a microwave emitter, or a UV or blue light emitter, to the liquid precursor material. In some embodiments, curing can include adding a polymerization agent to the liquid precursor material. In some embodiments, curing can include providing charges to the liquid precursor material through a catalytic, electrochemical, or photolytic process. In some embodiments, curing can include applying pressure, sound waves, or vibrations to the liquid precursor material.

In some embodiments, curing may include a first partial curing operation and a second full curing operation. For example, the first curing operation may include heating the liquid precursor material to a first temperature from about 60° C. to about 200° C. and the second curing operation may include heating the partially cured material to a second temperature higher than the first temperature. In some embodiments, the partially cured liquid precursor material can be treated (e.g., patterned, selectively removed, etc.) between the first and second curing operations.

At 1406, the method 1400 may optionally include forming a third layer bonded to the second layer opposite the first layer. The third layer may be formed by applying a liquid precursor to the second layer that can be the same or different from the liquid precursor used to form the second layer. The third layer can be cured in any of the same ways as the second layer can be.

At 1408, the method 1400 may include forming a semiconductor device package comprising a semiconductor die formed from the semiconductor wafer. For example, the semiconductor wafer may be singulated to form the semiconductor die. In some embodiments, singulating includes selectively removing portions of the second layer in a pattern defining a perimeter of the semiconductor die and then cutting the first layer in the same pattern. In some embodiments, cutting is performed using a breaker or a wire saw. In some embodiments, cutting is performed by exposing the first layer to radiation causing thermal fracturing. The singulated die can then be packaged as is known in the art to form a semiconductor device package.

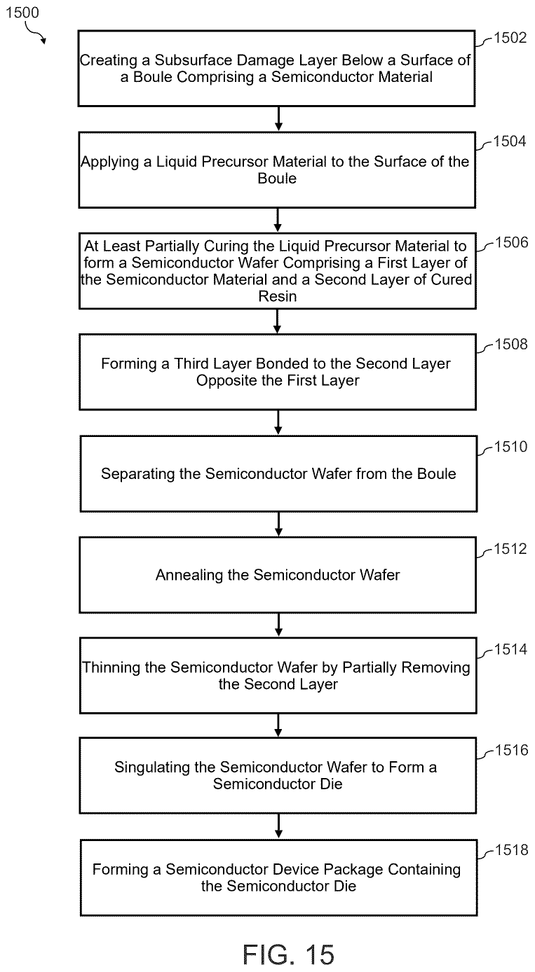

FIG. 15 depicts a flow chart diagram of an example method 1500 according to aspects of the present disclosure. The method 1500 depicts operations in a particular order for purposes of illustration and discussion. Those of ordinary skill in the art, using the disclosures provided herein, will understand that the various steps or operations of the method may be adapted, rearranged, omitted, include steps not illustrated, and/or modified in various ways without deviating from the scope of the present disclosure.

At 1502, the method 1500 includes creating a subsurface damage layer (i.e., a modified subsurface layer) below a surface of a boule comprising a semiconductor material. The semiconductor boule may be made of a variety of materials. For instance, in some embodiments, the semiconductor workpiece may include silicon carbide or a group III-nitride.

In some embodiments, the modified subsurface layer may be formed by irradiating the boule with a radiation source, such as one or more laser sources that provide damage-inducing emission of radiation. In some embodiments, the modified subsurface layer may be formed by ion implantation of an impurity, such as by directing an ion beam at the boule.

The subsurface damage layer may comprise voids, dopants, crystallographic 1d or 2d defects, broken bonds, recrystallized material, and/or amorphized material.

The depth of the subsurface damage layer may be relatively shallow, such as about 100 μm or less, such as about 80 μm or less, such as about 50 μm or less, such as about 30 μm or less, such as about 10 μm or less, such as about 5 μm or less, such as about 3 μm or less, such as about 2 μm or less, such as about 1 μm or less below the surface of the boule.

At 1504, the method 1500 may include applying a liquid precursor material to the surface of the semiconductor boule. The semiconductor boule may be made of a variety of materials. For instance, in some embodiments, the semiconductor boule may include silicon carbide or a group III-nitride.

As described above, the liquid precursor material may comprise a furan- or ether-based curable resin optionally comprising a solvent and/or additives. Additives may include glycolate functionalized substances (e.g., a metal or metalloid or a carbide, nitride, or oxide thereof) comprising functional groups such as glycolate, diethylene glycolate, and/or glycerolate functional groups.

Application of the liquid precursor material may be by spin-coating, slip casting, doctor blading, dipping, screen printing, stamping, spray coating, brushing, rolling, condensing, electrostatic deposition, or laminating the precursor material on the surface of the semiconductor material. In some embodiments, the liquid precursor material is applied to the surface of the semiconductor material in a non-uniform pattern. Optionally, the liquid precursor material is applied uniformly to the surface of the semiconductor material and then treated to form a layer of non-uniform thickness. Such treatment may occur before or after curing, or after partially curing but before fully curing, the resin.

At 1506, the method 1500 may include at least partially curing the liquid precursor material to form a semiconductor wafer comprising a first layer of the semiconductor material and a second layer of cured resin. As described above, curing may include heating the liquid precursor material, such as heating the liquid precursor material to a temperature from about 60° C. to about 800° C. In some embodiments, curing can include applying a radiation source, such as an infrared source, a plank emitter, an RF emitter, a microwave emitter, or a UV or blue light emitter, to the liquid precursor material. In some embodiments, curing can include adding a polymerization agent to the liquid precursor material. In some embodiments, curing can include providing charges to the liquid precursor material through a catalytic, electrochemical, or photolytic process. In some embodiments, curing can include applying pressure, sound waves, or vibrations to the liquid precursor material.

In some embodiments, curing may include a first partial curing operation and a second full curing operation (e.g., an annealing operation 1512 as described below). For example, the first curing operation may include heating the liquid precursor material to a first temperature from about 60° C. to about 200° C. In other embodiments, the liquid precursor material may be fully cured at 1506 by heating the liquid precursor to a temperature from about 60° C. to about 800° C. or otherwise fully curing the resin.

At 1508, the method 1500 may optionally include forming a third layer bonded to the second layer opposite the first layer. The third layer may be formed by applying a liquid precursor to the second layer that can be the same or different from the liquid precursor used to form the second layer. The third layer can be cured in any of the same ways as the second layer can be.

At 1510, the method 1500 may include separating the semiconductor wafer from the boule. Separation may occur at the subsurface damage layer. Separation may be caused by swelling or expansion of the resin during a curing or heating operation. In some embodiments, separating may include a mechanical fracturing process, ultrasonic fracturing process, or other fracturing process to fracture and separate the semiconductor wafer from the remaining portion of the semiconductor boule. In some embodiments, a wire saw may be used to separate the wafer from the boule. If a wire saw is used, the formation of the modified subsurface layer can be omitted.

At 1512, the method 1500 may include annealing the semiconductor wafer. Annealing may include heating the wafer to a relatively high temperature, such as up to about 800° C. to fully harden the resin layer(s).

At 1514, the method 1500 may include thinning the semiconductor wafer by partially removing the second and/or third layers. Thinning may include machining the backside of the wafer to obtain the desired final thickness and surface properties of the backside layer. However, thinning generally does not include removing all of the support layer(s) formed on the semiconductor material.

At 1516, the method 1500 may include singulating the semiconductor wafer to form a semiconductor die. In some embodiments, singulating includes selectively removing portions of the second layer in a pattern defining a perimeter of the semiconductor die and then cutting the first layer in the same pattern. In some embodiments, cutting is performed using a breaker, a circular saw, or a wire saw. In some embodiments, cutting is performed by exposing the first layer to radiation causing thermal fracturing.

Prior to singulating, the wafer may undergo surface processing operations such as etching, electrochemical etching, laser ablation, grinding, polishing, lapping, CMP, and the like. The wafer may undergo further semiconductor fabrication operations, such as epitaxy operations, etching, and the like.

At 1518, the method 1500 may include forming a semiconductor device package comprising the semiconductor die. For example, the singulated die can be packaged as is known in the art to form a semiconductor device package. Such a package may include one or more semiconductor die and one or more terminals that may protrude laterally from the semiconductor device package. The semiconductor device package may be included in a power semiconductor device assembly comprising the package mounted on a support structure using an attach layer. The semiconductor device package may include a variety of semiconductor die and devices. For instance, the semiconductor package may include silicon-carbide based semiconductor die with one or more semiconductors devices such as a silicon carbide-based MOSFETs and/or silicon carbide-based Schottky diodes on the one or more semiconductor dies. Additionally, or alternatively, the semiconductor device package may include Group III nitride-based devices such as Group III nitride-based high electron mobility transistors (HEMTs) on the one or more semiconductor die. In some embodiments, the semiconductor device package may be a power module.

Example aspects of the present disclosure are set forth below. Any of the below features or examples may be used in combination with any of the embodiments or features provided in the present disclosure.

In one aspect, the present disclosure provides an example wafer. In some implementations, the example wafer includes a first layer comprising a semiconductor material. In some implementations, the example wafer includes a second layer comprising a cured furan- or ether-based resin bonded to the first layer.

In some implementations of the example semiconductor wafer, the semiconductor material includes a wide-bandgap semiconductor material.

In some implementations of the example semiconductor wafer, the semiconductor material includes silicon carbide.

In some implementations of the example semiconductor wafer, the first layer has a thickness of about 100 μm or less.

In some implementations of the example semiconductor wafer, the resin includes an additive.

In some implementations of the example semiconductor wafer, the additive includes a glycolate functionalized substance.

In some implementations of the example semiconductor wafer, the glycolate functionalized substance includes functional groups selected from glycolate, diethylene glycolate, glycerolate, or combinations thereof.

In some implementations of the example semiconductor wafer, the substance includes a low dimensional carbon material or a metal or metalloid or a carbide, nitride, or oxide of the metal or metalloid.

In some implementations of the example semiconductor wafer, the metal or metalloid includes silicon, tantalum, niobium, tungsten, hafnium, titanium, and/or molybdenum.

In some implementations of the example semiconductor wafer, the resin contains a plasticizer.

In some implementations of the example semiconductor wafer, a thickness of the second layer is from about 100 μm to about 500 μm.

In some implementations of the example semiconductor wafer, a thickness of the second layer is non-uniform.

In some implementations of the example semiconductor wafer, a ratio of a coefficient of thermal expansion of the first layer to a coefficient of thermal expansion of the second layer is from about 0.8 to about 1.2 at a temperature from −50° C. to 2500° C.

In some implementations of the example semiconductor wafer, a volume resistivity of the second layer is from about 2×10⁻⁸ Ω·m to about 1.5×10⁻⁴ Ω·m.

In some implementations of the example semiconductor wafer, a thermal conductivity of the second layer is from about 1 W/mK to about 500 W/mK.

In some implementations of the example semiconductor wafer, a concentration of mobile elements in the second layer is about 1 ppm or less.

In some implementations, the example semiconductor wafer includes a third layer bonded to the second layer opposite the first layer.

In some implementations of the example semiconductor wafer, the third layer has a volume resistivity of 1.5×10⁻⁴ Ω·m or less and a ratio of a coefficient of thermal expansion of the first layer to a coefficient of thermal expansion of the second layer is from about 0.8 to about 1.2 at a temperature from −50° C. to 2500° C.

In some implementations of the example semiconductor wafer, the third layer includes a resin and metal particles dispersed within the resin.

In some implementations of the example semiconductor wafer, the third layer includes a carbide, silicide, nitride, or oxide of tungsten, tantalum, niobium, hafnium, titanium, molybdenum, or a combination thereof.

In another aspect, the present disclosure provides an example wafer. In some implementations, the example wafer includes a first layer comprising a semiconductor material and having a thickness of about 50 μm or less. In some implementations, the example wafer includes a second layer comprising a cured ether- or furan-based resin bonded to the first layer.

In some implementations of the example semiconductor wafer, the semiconductor material includes a wide-bandgap semiconductor material.

In some implementations of the example semiconductor wafer, the semiconductor material includes silicon carbide.

In some implementations of the example semiconductor wafer, the resin includes an additive.

In some implementations of the example semiconductor wafer, the additive includes a glycolate functionalized substance.

In some implementations of the example semiconductor wafer, the glycolate functionalized substance includes functional groups selected from glycolate, diethylene glycolate, glycerolate, or combinations thereof.

In some implementations of the example semiconductor wafer, the substance includes a metal or metalloid or a carbide, nitride, or oxide of the metal or metalloid.

In some implementations of the example semiconductor wafer, the metal or metalloid includes silicon, tantalum, niobium, tungsten, hafnium, titanium, and/or molybdenum.

In some implementations of the example semiconductor wafer, the resin contains a plasticizer.

In some implementations of the example semiconductor wafer, the thickness of the second layer is from about 100 μm to about 500 μm.

In some implementations of the example semiconductor wafer, a thickness of the second layer is non-uniform.

In some implementations of the example semiconductor wafer, a ratio of a coefficient of thermal expansion of the first layer to a coefficient of thermal expansion of the second layer is from about 0.8 to about 1.2 at a temperature from −50° C. to 2500° C.

In some implementations of the example semiconductor wafer, a volume resistivity of the second layer is from about 2×10⁻⁸ Ω·m to about 1.5×10⁻⁴ Ω·m.

In some implementations of the example semiconductor wafer, a thermal conductivity of the second layer is from about 1 W/mK to about 500 W/mK.

In some implementations of the example semiconductor wafer, a concentration of mobile elements in the second layer is about 100 ppm or less.

In some implementations, the example semiconductor wafer includes a third layer bonded to the second layer opposite the first layer.

In some implementations of the example semiconductor wafer, the third layer has a volume resistivity of 1.5×10⁻⁴ Ω·m or less and a ratio of a coefficient of thermal expansion of the first layer to a coefficient of thermal expansion of the second layer is from about 0.8 to about 1.2 at a temperature from −50° C. to 2500° C.

In some implementations of the example semiconductor wafer, the third layer includes a resin and metal particles dispersed within the resin.

In some implementations of the example semiconductor wafer, the third layer includes a carbide of tungsten, tantalum, niobium, hafnium, titanium, or molybdenum, or a combination thereof.

In some implementations of the example semiconductor wafer, the resin includes furan-based resin.

In another aspect, the present disclosure provides an example semiconductor device package. In some implementations, the example semiconductor device package includes a semiconductor die and one more terminals protruding from the semiconductor device package, wherein the semiconductor die includes a first layer comprising a semiconductor material and a second layer comprising a cured resin bonded to the first layer.

In some implementations of the example semiconductor device package, the semiconductor material includes a wide-bandgap semiconductor material.

In some implementations of the example semiconductor device package, the semiconductor material includes silicon carbide.

In some implementations of the example semiconductor device package, the resin includes an additive.

In some implementations of the example semiconductor device package, the additive includes a glycolate functionalized substance.

In some implementations of the example semiconductor device package, the glycolate functionalized substance includes functional groups selected from glycolate, diethylene glycolate, glycerolate, or combinations thereof.

In some implementations of the example semiconductor device package, the substance includes a metal or metalloid or a carbide, nitride, or oxide of the metal or metalloid.

In some implementations of the example semiconductor device package, the metal or metalloid includes silicon, tantalum, niobium, tungsten, hafnium, titanium, and/or molybdenum.

In some implementations of the example semiconductor device package, the resin contains a plasticizer.

In some implementations of the example semiconductor device package, a thickness of the second layer is from about 100 μm to about 500 μm.

In some implementations of the example semiconductor device package, a thickness of the second layer is non-uniform.

In some implementations of the example semiconductor device package, a ratio of a coefficient of thermal expansion of the first layer to a coefficient of thermal expansion of the second layer is from about 0.8 to about 1.2 at a temperature from −50° C. to 2500° C.

In some implementations of the example semiconductor device package, a volume resistivity of the second layer is from about 2×10⁻⁸ Ω·m to about 1.5×10⁻⁴ Ω·m.

In some implementations of the example semiconductor device package, a thermal conductivity of the second layer is from about 1 W/mK to about 500 W/mK.

In some implementations of the example semiconductor device package, a concentration of mobile elements in the second layer is about 100 ppm or less.

In some implementations, the example semiconductor device package includes a third layer bonded to the second layer opposite the first layer.

In some implementations of the example semiconductor device package, the third layer has a volume resistivity of 1.5×10⁻⁴ Ω·m or less and a ratio of a coefficient of thermal expansion of the first layer to a coefficient of thermal expansion of the second layer is from about 0.8 to about 1.2 at a temperature from −50° C. to 2500° C.

In some implementations of the example semiconductor device package, the third layer includes a resin and metal particles dispersed within the resin.

In some implementations of the example semiconductor device package, the third layer includes a carbide of tungsten, tantalum, niobium, hafnium, titanium, or molybdenum, or a combination thereof.

In some implementations of the example semiconductor device package, the resin includes furan- or ether-based resin.

In some implementations of the example semiconductor device package, the first layer has a thickness of about 100 μm or less.

In another aspect, the present disclosure provides an example process. In some implementations, the example process includes applying a liquid precursor material to a surface of a semiconductor material. In some implementations, the example process includes curing the liquid precursor material to form a semiconductor wafer comprising a first layer of the semiconductor material and a second layer of cured resin. In some implementations, the example process includes forming a semiconductor device package comprising a semiconductor die formed from the semiconductor wafer.

In some implementations of the example process, the semiconductor material includes a wide-bandgap semiconductor material.

In some implementations of the example process, the semiconductor material includes silicon carbide.

In some implementations of the example process, the resin includes an additive.

In some implementations of the example process, the additive includes a glycolate functionalized substance.

In some implementations of the example process, the glycolate functionalized substance includes functional groups selected from glycolate, diethylene glycolate, glycerolate, or combinations thereof.

In some implementations of the example process, the substance includes a metal or metalloid or a carbide, nitride, or oxide of the metal or metalloid.

In some implementations of the example process, the metal or metalloid includes silicon, tantalum, niobium, tungsten, hafnium, titanium, and/or molybdenum.

In some implementations of the example process, the resin contains a plasticizer.

In some implementations of the example process, a thickness of the second layer is from about 100 μm to about 500 μm.

In some implementations of the example process, a thickness of the second layer is non-uniform.

In some implementations of the example process, a ratio of a coefficient of thermal expansion of the first layer to a coefficient of thermal expansion of the second layer is from about 0.8 to about 1.2 at a temperature from −50° C. to 2500° C.

In some implementations of the example process, a volume resistivity of the second layer is from about 2×10⁻⁸ Ω·m to about 1.5×10⁻⁴ Ω·m.

In some implementations of the example process, a thermal conductivity of the second layer is from about 1 W/mK to about 500 W/mK.

In some implementations of the example process, a concentration of mobile elements in the second layer is about 100 ppm or less.

In some implementations, the example process includes forming a third layer bonded to the second layer opposite the first layer.

In some implementations of the example process, the third layer has a volume resistivity of 1.5×10⁻⁴ Ω·m or less and a ratio of a coefficient of thermal expansion of the first layer to a coefficient of thermal expansion of the second layer is from about 0.8 to about 1.2 at a temperature from −50° C. to 2500° C.

In some implementations of the example process, the third layer includes a resin and metal particles dispersed within the resin.

In some implementations of the example process, the third layer includes a carbide of tungsten, tantalum, niobium, hafnium, titanium, or molybdenum, or a combination thereof.

In some implementations, the example process includes removing at least a portion of the third and/or second layer after one or more semiconductor processing steps.

In some implementations of the example process, the resin includes furan- or ether-based resin.

In some implementations of the example process, the first layer has a thickness of about 100 μm or less.

In some implementations of the example process, the liquid precursor material includes a solvent.

In some implementations of the example process, applying the precursor material includes spin-coating, slip casting, doctor blading, dipping, screen printing, stamping, spray coating, brushing, rolling, condensing, electrostatic deposition, or laminating the precursor material on the surface of the semiconductor material.

In some implementations of the example process, the liquid precursor material is applied to the surface of the semiconductor material in a non-uniform pattern.

In some implementations of the example process, the liquid precursor material is applied uniformly to the surface of the semiconductor material and then treated to form a layer of non-uniform thickness.

In some implementations of the example process, the liquid precursor material is at least partially cured before it is applied to the surface of the semiconductor material.

In some implementations of the example process, curing includes heating the liquid precursor material to a temperature from about 60° C. to about 800° C.

In some implementations of the example process, curing includes applying a radiation source to the liquid precursor material.

In some implementations of the example process, the radiation source includes an infrared source, a plank emitter, an RF emitter, a microwave emitter, or a UV or blue light emitter.

In some implementations of the example process, curing includes adding a polymerization agent to the liquid precursor material.

In some implementations of the example process, curing includes providing charges to the liquid precursor material through a catalytic, electrochemical, or photolytic process.

In some implementations of the example process, curing includes applying pressure, sound waves, or vibrations to the liquid precursor material.

In some implementations of the example process, curing includes applying sound waves and the liquid precursor material acts as an acoustic waveguide or acoustic coupler.

In some implementations of the example process, curing includes partially curing the liquid precursor material in a first curing operation and fully curing the liquid precursor material in a second curing operation.

In some implementations of the example process, the first curing operation includes heating the liquid precursor material to a first temperature from about 60° C. to about 200° C. and the second curing operation includes heating the partially cured material to a second temperature higher than the first temperature.

In some implementations, the example process includes treating the partially cured liquid precursor material or the semiconductor material between the first and second curing operations.

In some implementations of the example process, the liquid precursor material is applied to the surface of a semiconductor boule and the process further includes creating a subsurface damage layer in the semiconductor boule before applying the liquid precursor material.

In some implementations of the example process, the subsurface damage layer is created at a depth from about 5 μm to about 100 μm below the surface of the semiconductor boule.

In some implementations of the example process, creating the subsurface damage layer includes a laser fracturing process.

In some implementations, the example process includes separating the semiconductor material at the subsurface damage layer to form the semiconductor wafer.

In some implementations of the example process, the liquid precursor material is partially cured before separating and fully cured after separating.

In some implementations of the example process, separating includes applying thermal energy to the liquid precursor material causing the semiconductor material to separate at the subsurface damage layer.

In some implementations of the example process, the thermal energy is applied by a thermal energy source comprising a radiation source, RF heating, Eddy currents, or injected currents.

In some implementations, the example process includes bringing an additional layer susceptible to the thermal energy source in contact with a surface of the liquid precursor material prior to applying the thermal energy.

In some implementations of the example process, the process does not include an operation of backside metallization.

In some implementations, the example process includes annealing the semiconductor wafer.

In some implementations, the example process includes thinning the semiconductor wafer by partially removing the second layer.

In some implementations, the example process includes singulating the semiconductor wafer to form the semiconductor die.

In some implementations of the example process, singulating includes selectively removing portions of the second layer in a pattern defining a perimeter of the semiconductor die and then cutting the first layer in the same pattern.

In some implementations of the example process, cutting is performed using a breaker, wire saw, or circular saw.

In some implementations of the example process, cutting is performed by exposing the first layer to radiation causing thermal fracturing.

In another aspect, the present disclosure provides an example process. In some implementations, the example process includes at least partially curing the liquid precursor material to form a semiconductor wafer comprising a first layer of the semiconductor material and a second layer of cured resin. In some implementations, the example process includes separating the semiconductor wafer from the boule.

In some implementations of the example process, the semiconductor material includes a wide-bandgap semiconductor material.

In some implementations of the example process, the semiconductor material includes silicon carbide.

In some implementations of the example process, the resin includes an additive.

In some implementations of the example process, the additive includes a glycolate functionalized substance.

In some implementations of the example process, the glycolate functionalized substance includes functional groups selected from glycolate, diethylene glycolate, glycerolate, or combinations thereof.

In some implementations of the example process, the substance includes a metal or metalloid or a carbide, nitride, or oxide of the metal or metalloid.

In some implementations of the example process, the metal or metalloid includes silicon, tantalum, niobium, tungsten, hafnium, titanium, and/or molybdenum.

In some implementations of the example process, the resin contains a plasticizer.

In some implementations of the example process, a thickness of the second layer is from about 100 μm to about 500 μm.

In some implementations of the example process, a thickness of the second layer is non-uniform.

In some implementations of the example process, a ratio of a coefficient of thermal expansion of the first layer to a coefficient of thermal expansion of the second layer is from about 0.8 to about 1.2 at a temperature from −50° C. to 2500° C.

In some implementations of the example process, a volume resistivity of the second layer is from about 2×10⁻⁸ Ω·m to about 1.5×10⁻⁴ Ω·m.

In some implementations of the example process, a thermal conductivity of the second layer is from about 1 W/mK to about 500 W/mK.

In some implementations of the example process, a concentration of mobile elements in the second layer is about 100 ppm or less.

In some implementations, the example process includes forming a third layer bonded to the second layer opposite the first layer.

In some implementations of the example process, the third layer has a volume resistivity of 1.5×10⁻⁴ Ω·m or less and a ratio of a coefficient of thermal expansion of the first layer to a coefficient of thermal expansion of the second layer is from about 0.8 to about 1.2 at a temperature from −50° C. to 2500° C.

In some implementations of the example process, the third layer includes a resin and metal particles dispersed within the resin.

In some implementations of the example process, the third layer includes a carbide of tungsten, tantalum, niobium, hafnium, titanium, or molybdenum, or a combination thereof.

In some implementations, the example process includes removing at least a portion of the third and/or second layer after one or more semiconductor processing steps.

In some implementations of the example process, the resin includes furan-based resin.

In some implementations of the example process, the first layer has a thickness of about 100 μm or less.

In some implementations of the example process, the liquid precursor material includes a solvent.

In some implementations of the example process, applying the precursor material includes spin-coating, slip casting, doctor blading, dipping, screen printing, stamping, spray coating, brushing, rolling, condensing, electrostatic deposition, or laminating the precursor material on the surface of the semiconductor material.

In some implementations of the example process, the liquid precursor material is applied to the surface of the semiconductor material in a non-uniform pattern.

In some implementations of the example process, the liquid precursor material is applied uniformly to the surface of the semiconductor material and then treated to form a layer of non-uniform thickness.

In some implementations of the example process, the liquid precursor material is at least partially cured before it is applied to the surface of the semiconductor material.

In some implementations of the example process, at least partially curing includes heating the liquid precursor material to a temperature from about 60° C. to about 800° C.

In some implementations of the example process, at least partially curing includes applying a radiation source to the liquid precursor material.

In some implementations of the example process, the radiation source includes an infrared source, a plank emitter, an RF emitter, a microwave emitter, or a UV or blue light emitter.

In some implementations of the example process, at least partially curing includes adding a polymerization agent to the liquid precursor material.

In some implementations of the example process, at least partially curing includes providing charges to the liquid precursor material through a catalytic, electrochemical, or photolytic process.

In some implementations of the example process, at least partially curing includes applying pressure, sound waves, or vibrations to the liquid precursor material.

In some implementations of the example process, curing includes applying sound waves and the liquid precursor material acts as an acoustic waveguide or acoustic coupler.

In some implementations of the example process, at least partially curing includes partially curing the liquid precursor material in a first curing operation and fully curing the liquid precursor material in a second curing operation.

In some implementations of the example process, the first curing operation includes heating the liquid precursor material to a first temperature from about 60° C. to about 200° C. and the second curing operation includes heating the partially cured material to a second temperature higher than the first temperature.

In some implementations of the example process, the first curing operation is performed before separating the semiconductor wafer from the boule and the second curing operation is performed after separating the semiconductor wafer from the boule.

In some implementations of the example process, the subsurface damage layer is created at a depth from about 5 μm to about 100 μm below the surface of the boule.

In some implementations of the example process, creating the subsurface damage layer includes a laser fracturing process.

In some implementations of the example process, separating includes applying thermal energy to the liquid precursor material causing the semiconductor material to separate at the subsurface damage layer.

In some implementations of the example process, the thermal energy is applied by a thermal energy source comprising a radiation source, RF heating, Eddy currents, or injected currents.

In some implementations, the example process includes bringing an additional layer susceptible to the thermal energy source in contact with a surface of the liquid precursor material prior to applying the thermal energy.

In some implementations, the example process includes annealing the semiconductor wafer.

In some implementations, the example process includes thinning the semiconductor wafer by partially removing the second layer.

In some implementations, the example process includes singulating the semiconductor wafer to form a semiconductor die.

In some implementations of the example process, singulating includes selectively removing portions of the second layer in a pattern defining a perimeter of the semiconductor die and then cutting the first layer in the same pattern.

In some implementations of the example process, cutting is performed using a breaker, wire saw, or circular saw.

In some implementations of the example process, cutting is performed by exposing the first layer to radiation causing thermal fracturing.

In some implementations, the example process includes forming a semiconductor device package comprising the semiconductor die.

In another aspect, the present disclosure provides an example process. In some implementations, the example process includes applying a liquid precursor material to a surface of the semiconductor material. In some implementations, the example process includes at least partially curing the liquid precursor material to form a semiconductor wafer comprising the semiconductor material and a layer of cured resin. In some implementations, the example process includes separating a layer of semiconductor material from a remaining portion of the semiconductor material.

In another aspect, the present disclosure provides an example process. In some implementations, the example process includes applying a liquid precursor material to a surface of the semiconductor wafer. In some implementations, the example process includes at least partially curing the liquid precursor material to form a semiconductor wafer comprising the semiconductor material and a layer of cured resin. In some implementations, the example process includes separating a semiconductor die from the semiconductor wafer.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A semiconductor wafer, the semiconductor wafer comprising:
a first layer comprising a semiconductor material; and
a second layer comprising a cured furan- or ether-based resin bonded to the first layer.

2. The semiconductor wafer of claim 1, wherein the semiconductor material comprises a wide-bandgap semiconductor material.

3. The semiconductor wafer of claim 1, wherein the semiconductor material comprises silicon carbide.

4. The semiconductor wafer of claim 1, wherein the first layer has a thickness of about 100 μm or less.

5. The semiconductor wafer of claim 1, wherein the resin comprises an additive.

6. The semiconductor wafer of claim 5, wherein the additive comprises a glycolate functionalized substance.

7. The semiconductor wafer of claim 6, wherein the glycolate functionalized substance comprises functional groups selected from glycolate, diethylene glycolate, glycerolate, or combinations thereof.

8. The semiconductor wafer of claim 6, wherein the substance comprises a low dimensional carbon material or a metal or metalloid or a carbide, nitride, or oxide of the metal or metalloid.

9. The semiconductor wafer of claim 8, wherein the metal or metalloid comprises silicon, tantalum, niobium, tungsten, hafnium, titanium, and/or molybdenum.

10. The semiconductor wafer of claim 1, wherein the resin contains a plasticizer.

11. The semiconductor wafer of claim 1, wherein a thickness of the second layer is from about 100 μm to about 500 μm.

12. The semiconductor wafer of claim 1, wherein a thickness of the second layer is non-uniform.

13. The semiconductor wafer of claim 1, wherein a ratio of a coefficient of thermal expansion of the first layer to a coefficient of thermal expansion of the second layer is from about 0.8 to about 1.2 at a temperature from −50° C. to 2500° C.

14. The semiconductor wafer of claim 1, wherein a volume resistivity of the second layer is from about 2×10⁻⁸ Ω·m to about 1.5×10⁻⁴ Ω·m or a thermal conductivity of the second layer is from about 1 W/mK to about 500 W/mK.

15. The semiconductor wafer of claim 1, wherein a concentration of mobile elements in the second layer is about 1 ppm or less.

16. The semiconductor wafer of claim 1, further comprising a third layer bonded to the second layer opposite the first layer.

17. The semiconductor wafer of claim 16, wherein the third layer has a volume resistivity of 1.5×10⁻⁴ Ω·m or less and a ratio of a coefficient of thermal expansion of the first layer to a coefficient of thermal expansion of the second layer is from about 0.8 to about 1.2 at a temperature from −50° C to 2500° C.

18. The semiconductor wafer of claim 16, wherein the third layer comprises a resin and metal particles dispersed within the resin or wherein the third layer comprises a carbide, silicide, nitride, or oxide of tungsten, tantalum, niobium, hafnium, titanium, or molybdenum, or a combination thereof.

19. A semiconductor device package, the semiconductor device package comprising:
a semiconductor die and one more terminals protruding from the semiconductor device package, wherein the semiconductor die comprises a first layer comprising a semiconductor material and a second layer comprising a cured resin bonded to the first layer.

20. A process for forming a semiconductor wafer, the process comprising:
creating a subsurface damage layer below a surface of a boule comprising a semiconductor material;
applying a furan- or ether-based liquid precursor material to the surface of the boule;
at least partially curing the liquid precursor material to form a semiconductor wafer comprising a first layer of the semiconductor material and a second layer of cured resin; and
separating the semiconductor wafer from the boule.
